(19) United States
(12) Patent Application Publication
(10) Pub. No.: US 2017/0217785 A1
(43) Pub. Date: Aug. 3, 2017

(54) INORGANIC HALIDE PEROVSKITE NANOWIRES AND METHODS OF FABRICATION THEREOF

(71) Applicants: Peidong Yang, Kensington, CA (US); Letian Dou, Albany, CA (US); Dandan Zhang, Albany, CA (US); Minliang Lai, El Cerrito, CA (US); Andrew B. Wong, San Francisco, CA (US)

(72) Inventors: Peidong Yang, Kensington, CA (US); Letian Dou, Albany, CA (US); Dandan Zhang, Albany, CA (US); Minliang Lai, El Cerrito, CA (US); Andrew B. Wong, San Francisco, CA (US)

(73) Assignee: The Regents of the University of California, Oakland, CA (US)

(21) Appl. No.: 15/422,169

(22) Filed: Feb. 1, 2017

Related U.S. Application Data
(60) Provisional application No. 62/290,009, filed on Feb. 2, 2016.
(60) Provisional application No. 62/342,094, filed on May 26, 2016.
(60) Provisional application No. 62/399,845, filed on Sep. 26, 2016.
(60) Provisional application No. 62/428,939, filed on Dec. 1, 2016.

(51) Int. Cl. C01G 19/00; C30B 29/12; C30B 29/60; C01G 21/00; C30B 7/14

(52) U.S. Cl. CPC C01G 19/006; C01G 21/006; C30B 7/14; C30B 29/60; C30B 29/12; H01L 31/035227

(57) ABSTRACT

This disclosure provides systems, methods, and apparatus related to inorganic halide perovskite nanowires. In one aspect, a first solution comprising cesium oleate or rubidium oleate in a first organic solvent is provided. A second solution comprising a lead halide and a surfactant in a second organic solvent is provided. The halide is selected from a group consisting of chlorine, bromine, and iodine. The first solution and the second solution are mixed. A reaction between the cesium oleate or the rubidium oleate and the lead halide forms a plurality of nanowires comprising an inorganic lead halide perovskite.

### RELATED APPLICATIONS

This application claims priority to U.S. Provisional Patent Application Ser. No. 62/290,009, filed Feb. 2, 2016, to U.S. Provisional Patent Application Ser. No. 62/342,094, filed May 26, 2016, to U.S. Provisional Patent Application Ser. No. 62/399,845, filed Sep. 26, 2016, and to U.S. Provisional Patent Application Ser. No. 62/428,939, filed Dec. 1, 2016, all of which are herein incorporated by reference.

### STATEMENT OF GOVERNMENT SUPPORT

This invention was made with government support under Contract No. DE-AC02-05CH11231 awarded by the U.S. Department of Energy. The government has certain rights in this invention.

### TECHNICAL FIELD

This disclosure relates generally to perovskites and more particularly to inorganic halide perovskite nanowires.

### BACKGROUND

Halide perovskites have been demonstrated to be a promising class of materials for optoelectronic applications, including high-efficiency photovoltaic cells, light-emitting diodes, lasers, and photodetectors. Advantages of these compounds include their excellent charge-transport properties and broad chemical tunability. While recent studies have been mostly focused on hybrid organic-inorganic compounds, the study of their inorganic analogues, like AMX₃ (A=Rb, Cs; M=Ge, Sn, Pb; X=Cl, Br, I), is limited.

Previous studies on the all-inorganic halide perovskites have revealed that these materials have great potential in optoelectronic applications. CsGeX₃ are known for their nonlinear optical properties and are potentially useful for nonlinear optics in the mid-infrared and infrared regions. CsSnI₃₋ₓFₓ has been demonstrated to be an effective hole-transport material and is able to replace the problematic organic liquid electrolytes in dye-sensitized solar cells. Theoretical calculations on ASnX₃ (A=Cs, CH₃NH₃, NH₂CH═NH₂; X=Cl, I) suggested that their electronic properties are strongly depend on the structure of the inorganic SnX₆ octahedral cage, which implies good prospects for the all-inorganic halide perovskites.

However, most of these studies were based on polycrystalline perovskite films deposited on substrates using vapor-phase co-evaporation or solution deposition of a mixture of AX and BX₂. The uncontrolled precipitation or evaporation of the perovskite produces large morphological variations, making it a non-ideal platform for understanding these materials' fundamental properties.

### SUMMARY

One innovative aspect of the subject matter described in this disclosure can be implemented in a nanowire comprising an inorganic halide perovskite. In some embodiments, the inorganic halide perovskite comprises ABX₃, where A is Cs or Rb, where B is Sn or Pb, and where X is Cl, Br, or I. In some embodiments, the nanowire has a cross-sectional dimension of less than 1000 nanometers.

Another innovative aspect of the subject matter described in this disclosure can be implemented in a method including providing a first solution comprising cesium oleate or rubidium oleate in a first organic solvent. A second solution comprising a lead halide and a surfactant in a second organic solvent is provided. The halide is selected from a group consisting of chlorine, bromine, and iodine. The first solution and the second solution are mixed. A reaction between the cesium oleate or the rubidium oleate and the lead halide forms a plurality of nanowires comprising an inorganic lead halide perovskite. In some embodiments, nanowires of the plurality of nanowires comprise ABX₃, where A is Cs or Rb, where B is Pb, and where X is Cl, Br, or I.

Another innovative aspect of the subject matter described in this disclosure can be implemented in a method including depositing lead iodide on a substrate. The lead iodide is contacted with a solution of a cesium halide or a rubidium halide in a first alcohol. The halide is selected from a group consisting of chlorine, bromine, and iodine. A reaction between the lead iodide and the cesium halide or the rubidium halide forms a plurality of nanowires comprising an inorganic lead halide perovskite. In some embodiments, the nanowires of the plurality of nanowires comprise ABX₃, where A is Cs or Rb, where B is Pb, and where X is Cl, Br, or I.

Another innovative aspect of the subject matter described in this disclosure can be implemented in a method including depositing a cesium halide or a rubidium halide on a substrate. The halide of the cesium halide or the rubidium halide is selected from a group consisting of chlorine, bromine, and iodine. The cesium halide or the rubidium halide is contacted with a solution of a tin halide or a lead halide in a first alcohol. The halide of the tin halide or the lead halide is selected from a group consisting of chlorine, bromine, and iodine. A reaction between the cesium halide or the rubidium halide and the tin halide or the lead halide forms a plurality of nanowires comprising an inorganic halide perovskite. In some embodiments, nanowires of the plurality of nanowires comprise ABX₃, where A is Cs or Rb, where B is Sn or Pb, and where X is Cl, Br, or I.

Details of one or more embodiments of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a flow diagram illustrating a fabrication process for inorganic lead halide perovskite nanowires.

FIGS. 2A-2F show the shape evolution of the as-prepared CsPbBr₃ nanostructures synthesized with different reaction times.

FIGS. 3A and 3B show the results of the structural characterization of CsPbBr₃ nanowires.

FIGS. 4A and 4B show the UV-vis absorption and photoluminescence spectra of CsPbX₃ (X=Br, I) NWs dispersed on a substrate.

FIGS. 5A and 5B show examples of flow diagrams illustrating an anion-exchange process performed with CsPbBr₃ and CsPbX₃ nanowires.

FIG. 6 shows examples of schematic representations of three CsPbX₃ (X=Cl, Br, I) orthorhombic crystal structures.

FIG. 7A shows TEM images of CsPb(Br—Cl)₃ NWs with various degrees of conversion with chloride anions. FIG. 7B shows TEM images of CsPb(Br—I)₃ NWs with various degrees of conversion with iodide anions.

FIG. 8 shows an example of a flow diagram illustrating process for separating small-diameter halide perovskite nanowires from other halide perovskite nanostructures.

FIG. 9 shows an example of a flow diagram illustrating a fabrication process for inorganic tin halide perovskite nanowires.

FIG. 10 shows an example of a micrograph of CsSnI₃ nanowires mixed with CsSnI₃ nanoparticles.

FIG. 11 shows an example of a flow diagram illustrating a fabrication process for inorganic lead halide perovskite nanowires.

FIGS. 12A-12D show the results of the structural characterization of CsPbBr₃ nanowires.

FIGS. 13A-13D show the results of the structural characterization of CsPbCl₃ nanowires.

FIGS. 14A-14C show the results of the structural characterization of CsPbI₃ nanowires.

FIG. 15 shows an example of a flow diagram illustrating a fabrication process for inorganic halide perovskite nanowires.

FIG. 16 shows an example of a micrograph of as-synthesized CsSnI₃ nanowires.

FIG. 17A shows the power-dependent emission spectra from a CsPbBr₃ nanowire. Narrow emission peaks at approximately 530 nm are indicative of lasing. A plot of inverse nanowire length (μm⁻¹) against mode spacing (meV) is shown in FIG. 17B and confirms that Fabry-Pérot type lasing is dominant.

FIG. 18 shows the power-dependent emission spectra from a CsPbCl₃ nanowire. Lasing occurs at approximately 425 nm. The inset shows an optical image of the same nanowire above the lasing threshold. The scale bar is 5 microns.

### DETAILED DESCRIPTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims.

In the following description, numerous specific details are set forth in order to provide a thorough understanding of the present invention. Particular example embodiments of the present invention may be implemented without some or all of these specific details. In other instances, well known process operations have not been described in detail in order not to unnecessarily obscure the present invention.

Various techniques and mechanisms of the present invention will sometimes be described in singular form for clarity. However, it should be noted that some embodiments include multiple iterations of a technique or multiple instantiations of a mechanism unless noted otherwise.

The terms “about” or “approximate” and the like are synonymous and are used to indicate that the value modified by the term has an understood range associated with it, where the range can be ±20%, ±15%, ±10%, ±5%, or ±1%. The term “substantially” is used to indicate that a value is close to a targeted value, where close can mean, for example, the value is within 80% of the targeted value, within 90% of the targeted value, within 95% of the targeted value, or within 99% of the targeted value.

Controlled synthesis of materials with high quality and well-defined morphology not only benefits fundamental research but also offers great promise for practical applications Examples include the development of semiconducting quantum dots (QDs), one-dimensional (1D) nanowires (NWs), and two-dimensional (2D) nanosheets, which can have optical and electrical properties superior to those of their bulk counterparts. Semiconductor NWs, in particular, currently attract widespread interest due to the great potential to advance fundamental and applied research toward new classes of inherently 1D photonic and electronic nanostructures. In terms of inorganic halide perovskites, with the exception of single-crystalline QDs, there have been no reports of 1D or 2D nanostructures.

In some embodiments, a nanowire of a nanosheet comprises an inorganic halide perovskite. A perovskite is a material with the same crystal structure as calcium titanium oxide (CaTiO₃). The general chemical formula for a perovskite is ABX₃, where A and B are two cations of different sizes, and X is an anion that bonds to both the A and B cations. The A cations are larger than the B cations. In some embodiments, the nanowire has a chemical formula ABX₃, where A is cesium (Cs) or rubidium (Rb), wherein B is tin (Sn) or lead (Pb), and where X is a halide such as chlorine (Cl), bromine (Br), or iodine (I).

In some embodiments, a nanowire has a cross-sectional dimension of less than 1000 nanometers (nm). For example, if the nanowire has a circular cross-section, the diameter of the nanowire is less than 1000 nm. For example, if the nanowire has a rectangular or square cross-section, a length of an edge of the rectangle or square is less than 1000 nm. In some embodiments, the nanowire has a length of about 100 nm to 30 microns.

In some embodiments, a nanosheet has a thickness of about 1 nanometer to 100 nanometers. In some embodiments, a nanosheet has a dimension on its planar surface of about 250 nanometers to 5 microns. For example, the nanosheet is circular, the diameter (i.e., the dimension on its planar surface) would be about 250 nanometers to 5 microns.

In some embodiments of the inorganic halide perovskite nanowire fabrication methods described below, long chain amines and short chain amines are used as ligands that cap the nanostructures during growth of the nanostructures. In some embodiments, organic acids perform a similar function. By combining different long and short chain amines, the growth of the structure can be directed such that nanowires or nanosheets are formed.

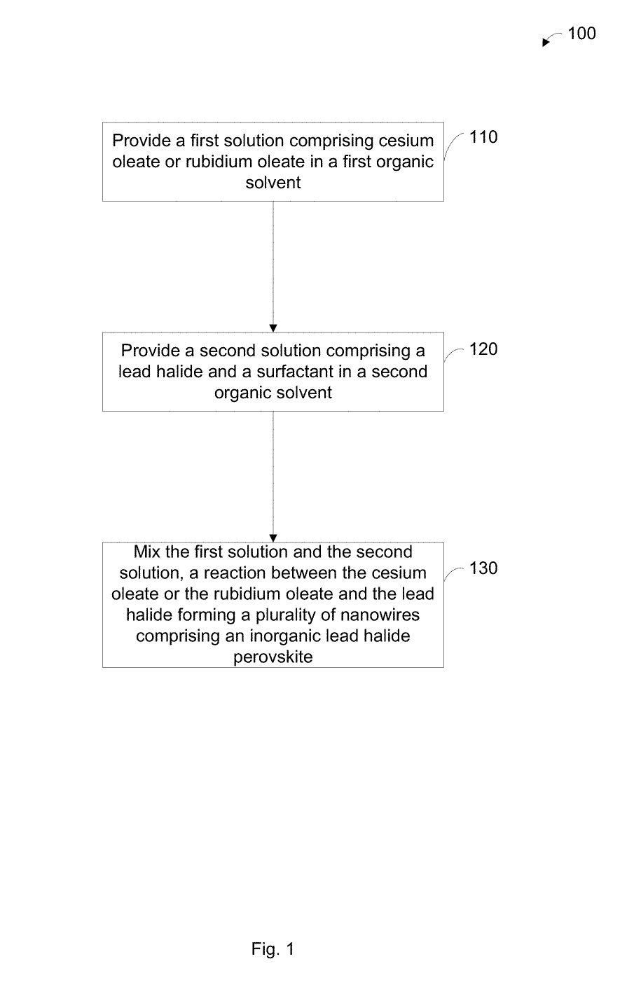

FIG. 1 shows an example of a flow diagram illustrating a fabrication process for inorganic lead halide perovskite nanowires. Some embodiments of the method 100 shown in FIG. 1 comprise a catalyst-free, solution-phase synthesis method of CsPbX₃ NWs. In some embodiments of the method 100, nanosheets are also generated. At block 110 of the method 100, a first solution comprising cesium oleate or rubidium oleate in a first organic solvent is provided. The first solution of cesium oleate or rubidium oleate may be formed, for example, by mixing cesium carbonate and oleic acid or rubidium carbonate and oleic acid in the first organic solvent. Other cesium/rubidium solutions also can be used. For example, in some embodiments, the first solution can be formed by mixing cesium carbonate or rubidium carbonate and a long chain acid (e.g., heptadecanoic acid (CH₃(CH₂)₁₅COOH)). The first organic solvent may comprise a non-coordinating solvent, such as a long chain olefin, for example. In some embodiments, the first solvent comprises octadecene (ODE). In some embodiments, block 110 is performed in an inert gas environment (e.g., argon (Ar) or nitrogen (N₂)).

At block 120, a second solution comprising a lead halide and a surfactant in a second organic solvent is provided. The halide is selected from a group consisting of chlorine, bromine, and iodine. The surfactant may comprise an amine. For example, in some embodiments, the surfactant comprises a surfactant selected from a group consisting of octylamine, oleylamine, oleic acid, and combinations thereof. Other amines with long carbon chains (e.g., octadecylamine) may also be used. In some embodiments, using octylamine (a type of short carbon chain amine) as a surfactant may increase the nanowire yield compared to other surfactants. The second organic solvent may comprise a non-coordinating solvent or a coordinating solvent. When a coordinating solvent is used, the size distribution (e.g., the cross-sectional dimension) of the nanowires may be wider than when using a non-coordinating solvent. In some embodiments, the second organic solvent comprises ODE. In some embodiments, the second organic solvent comprises oleylamine. In some embodiments, block 120 is performed in an inert gas environment.

At block 130, the first solution and the second solution are mixed. For example, the first solution may be poured into the second solution. A reaction between the cesium oleate or the rubidium oleate and the lead halide forms a plurality of nanowires comprising an inorganic lead halide perovskite. In some embodiments, block 130 is performed at about 130° C. to 250° C. In some embodiments, the mixture is held at about 130° C. to 250° C. for about 5 minutes to 20 hours. In some embodiments, block 130 is performed in an inert gas environment. In some embodiments, the plurality of nanowires formed at block 130 comprises ABX₃, wherein A is Cs or Rb, wherein B is Pb, and wherein X is Cl, Br, or I.

For example, when fabricating CsPbBr₃ or CsPbCl₃ nanowires, different combinations of different amines may be used as surfactants. In some embodiments, octylamine and oleylamine are used. In some embodiments, decylamine or dodecylamine combined with oleylamine is used. In some embodiments, an acid is not used in the fabrication of CsPbBr₃ or CsPbCl₃ nanowires. In some embodiments, when fabricating CsPbI₃ nanowires, oleylamine and oleic acid are used as surfactants.

Synthesis of CsPbX₃ NWs using an embodiment of the method 100 shown in FIG. 1 is described below. Detailed structural characterization revealed that the NWs formed by this method are single-crystalline with uniform growth direction, and crystallize in an orthorhombic phase. In some instances, CsPbBr₃ NWs having diameters of about 10 nm were formed. Optical measurements showed that both CsPbBr₃ and CsPbI₃ are photoluminescence (PL) active, with CsPbBr₃ showing strong PL, CsPbI₃ exhibiting a self-trapping effect, and both displaying temperature-dependent PL.

The preparation of CsPbX₃ NWs was performed under air-free conditions using Schlenk techniques by reacting cesium oleate with lead halide in the presence of oleic acid/octylamine and oleylamine in octadecene (ODE) at 130° C. to 250° C. A Cs-oleate solution was prepared by loading 0.4 g Cs₂CO₃ and 1.2 mL oleic acid (OA) in flask along with 15 mL ODE, degassing and drying under vacuum at 12° C. for 1 hour, and then heating under N₂ to 150° C. until all Cs₂CO₃ reacted with OA.

5 mL ODE and 0.18 mmol PbX₂ were loaded into a flask and degassed under vacuum for 1 hour at 120° C. Certain amounts of oleylamine (OLA) and oleic acid/octylamine were injected at 120° C. under N₂ (typically, 0.3 mL OLA, 0.4 mL OA for CsPbBr₃, 0.5 mL OLA, 0.8 mL OA for CsPbI₃). The temperature was raised to 150° C. and 1 hour was allowed to elapse for complete dissolution of the PbX₂ salt.

For the synthesis of CsPbBr₃ and CsPbCl₃ nanowires, the solution was kept at 150° C., and 0.6 mL of as-prepared Cs-oleate solution was quickly injected. After a certain duration, the reaction mixture was cooled by a water bath. For CsPbI₃ nanowires, higher temperatures (>180° C.) were needed for relative uniform nanowire growth. In a typical case, after complete dissolution of PbI₂ salt, the temperature was raised to 250° C., and 0.6 mL of as-prepared Cs-oleate solution was injected. After 5 minutes to 10 minutes, the reaction mixture was cooled by a water bath. To isolate the purify the CsPbX₃ nanowires, the crude solution was cooled down with a water bath and aggregated NWs were separated by centrifugation at 6000 rpm for 5 minutes and washed twice with hexane.

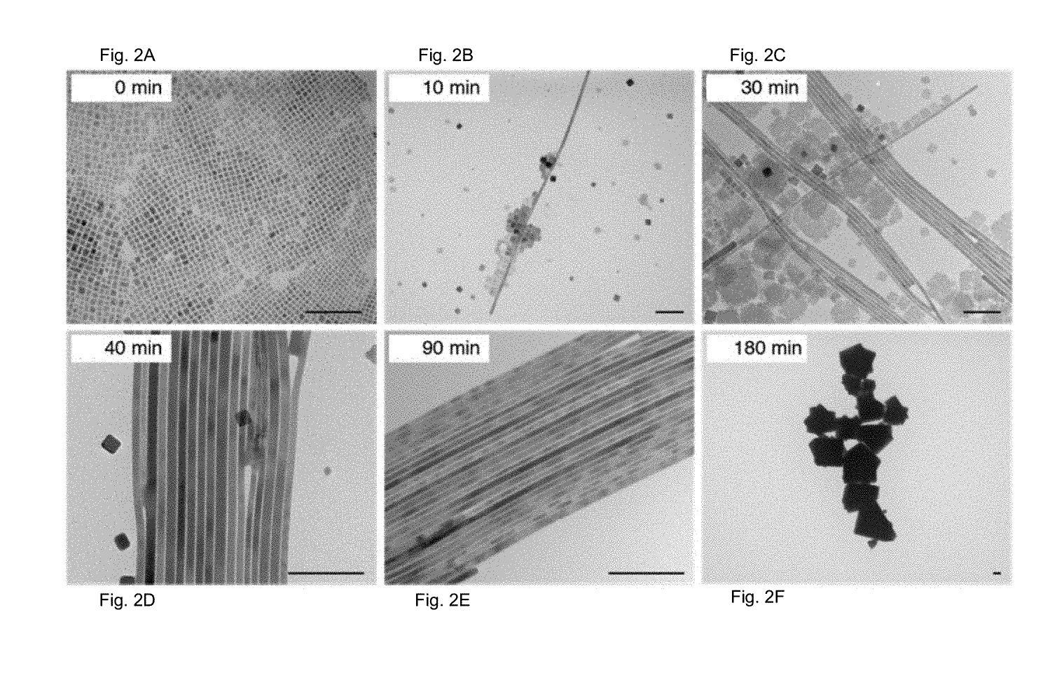

To analyze the NWs' formation mechanism, the reaction was quenched to room temperature at different points in time, and the respective intermediates were separated by centrifugation and examined using X-ray diffraction (XRD) and transmission electron microscopy (TEM). FIGS. 2A-2F show the shape evolution of as-prepared CsPbBr₃ nanostructures synthesized with different reaction times. The scale bar in each figure is 100 nm. For CsPbBr₃ NW synthesis, the reaction dynamics were studied at 150° C. At the initial stage (t<10 minutes), the reaction is dominated by the formation of nanocubes (NCs) with size ranging from 3 nm to 7 nm (FIG. 2A). After 10 minutes, a few thin NWs with diameters around 9 nm are found in the product (FIG. 2B). With increasing time, more NWs form while the amount of NCs decreases; in addition, there are some square-shaped nanosheets (NSs) in the product (FIG. 2C). At a later stage (40 minutes to 60 minutes) in the reaction, the NSs dissolved, and NWs with diameters uniformly below 12 nm (FIGS. 2D and 2E) and lengths up to 5 microns account for a greater proportion of the product, along with the formation of crystals with sizes larger than 200 nm. With longer time, the NWs gradually disappear, and the product consists mainly of the large crystals (FIG. 2F).

These morphologies do not represent discrete intermediates formed at specific reaction times, but evolve sequentially from each other. Consequently, different intermediates can coexist in the product at a given time during the reaction. The growth of CsPbI₃ NWs requires elevated temperatures (T>180° C.) and demonstrates much faster kinetics. As such, the reaction is less controllable and the size distribution of the NWs was wider, ranging from tens to hundreds of nanometers. The CsPbCl₃ NWs have also been synthesized at 150° C., but the proportion of the NWs in the product at different reaction stages was always relatively low.

Catalyst-free, solution-phase syntheses can be used to prepare nanostructures with low aspect ratio, such as rods and dots. The formation of high aspect ratio NWs in solution may be achieved by oriented attachment of nanocrystals or by anisotropic growth driven by high monomer concentrations with the assistance of surfactant capping. It is believed that the formation of the CsPbX₃ NWs here is likely not due to a dipole-driven one-dimensional oriented attachment of NCs, since no dimers or “oligomers” of NCs are observed in the products, and during the aging of a colloidal solution of the nanocrystals, there was no nanorod formation due to the dipole-driven attachment. In order to obtain a better understanding of the NWs' growth mechanism, further experiments have been conducted to investigate the influence of temperature, time, surfactants, and precursor concentration on the morphology of the product. A control experiment done by changing the reaction solvent from ODE to oleylamine shows much slower kinetics but with higher yield of NWs, which suggests the NW formation most likely proceeds through a surfactant-directed 1D growth mode.

Some parameters controlling nanowire formation are the reaction temperature, concentration of the reactants, and concentration and composition of the stabilizing agents. In the case of CsPbBr₃ nanowire synthesis, if the reaction temperature is too high, the stable phase during reaction will be a highly symmetric cubic phase, which lacks the inherent anisotropy of crystal structure, and thus can only yield nanocubes and large crystals. Notably, the reported reaction temperature is the temperature of the oil/salt bath, the actual reaction temperature of the reaction system will be lower.

In order to gain better understanding of the growth mechanism, control experiments were performed. First, when only using oleylamine as surfactant, it turns out that the PbBr₂ does not fully dissolve. This demonstrates that oleic acid is needed for coordinating with Pb²⁺ and decomposing the precursor to form monomers. Another control experiment was carried out by changing the reaction solvent from ODE to oleylamine while maintaining all other conditions. The reaction shows much slower kinetics and the yield of the nanowires is much higher (even though the size distribution becomes larger). ODE is a non-coordinating solvent, while oleylamine can serve as a capping ligand for Pb²⁺. The slower kinetics of the control experiment implies that the binding of oleylamine to Pb²⁺ can reduce the reactivity of the Pb²⁺ precursor, and maintain a higher monomer concentration after the nucleation stage, which is needed for anisotropic growth. Also, the significant increase of the yield of nanowires in the control experiments implies that oleylamine may preferentially bind to certain facets of CsPbX₃, and favor the anisotropic structure growth along certain direction.

CsPbX₃ bulk crystals exhibit a cubic perovskite structure in the highest temperature phase. Upon lowering the temperature, CsPbI₃ undergoes one phase transition, cubic-orthorhombic (328° C.), with a color change from dark to yellow. CsPbBr₃ has two phase transitions, cubic-tetragonal (130° C.)-orthorhombic (88° C.), with hardly any color change (orange). CsPbCl₃ shows three successive phase transitions, cubic-tetragonal (47° C.)-orthorhombic (42° C.)-monoclinic (37° C.), with hardly any color change (pale yellow).

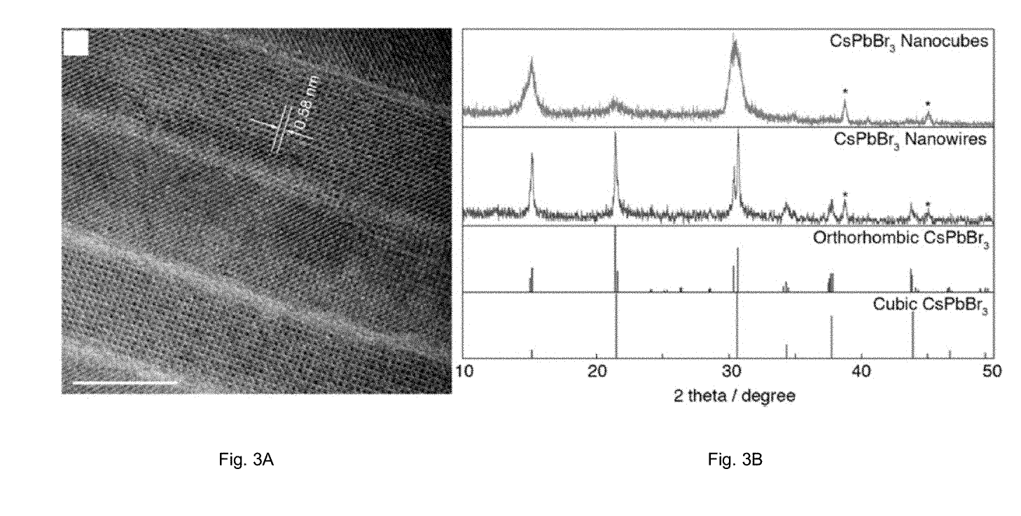

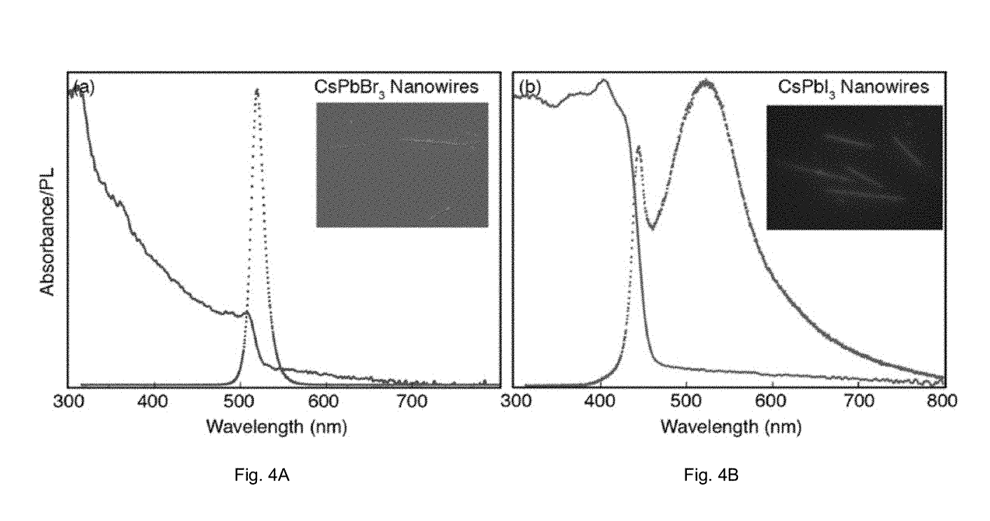

FIG. 3A shows a representative high-resolution TEM (HR-TEM) image of CsPbBr₃ NWs. The scale bar in FIG. 3A is 10 nm. FIG. 3B shows experimental XRD spectrum of CsPbBr₃ nanocubes and NWs, and standard XRD patterns for orthorhombic and cubic phases of CsPbBr₃. Extra peaks (labeled *) were caused by the XRD aluminum stage. The phase of CsPbBr₃ NWs needs careful determination because of the small difference between the XRD standard patterns of the orthorhombic and cubic phases. As shown in FIG. 3B, the key difference in distinguishing the orthorhombic phase from the cubic phase is the double peaks at ˜30°. The peak broadening caused by the small size of the CsPbBr₃ NCs makes it difficult to determine their exact phase, while the clear double peak at ˜30° confirms that the CsPbBr₃ NWs are grown in the orthorhombic phase. The HR-TEM images (FIG. 3A) show that the CsPbBr₃ NWs are single crystalline with uniform <110> growth direction. The XRD spectrum of CsPbBr₃ nanosheets also suffers severe peak broadening, making it difficult to tell its exact phase. Atomic force microscopy (AFM) images show the thickness of the nanosheets ranges from 0.5 to 2 nm. HR-TEM images of the sheets show lattice patterns with antiphase boundaries, which is commonly observed in oxide perovskites.

Both the yellow color of the crystal and the XRD pattern confirm that the CsPbI₃ NWs are in the orthorhombic phase. The HR-TEM images show that the CsPbI₃ NWs are single-crystalline, with uniform <100> growth direction. The exact phase of CsPbCl₃ cannot be determined with the X-ray diffractometer that was used because the resolution of the instrument cannot differentiate the closely spaced peaks.

The optical properties of the CsPbX₃ (X=Br, I) NWs were studied by measuring the UV-vis absorption and PL spectra of each material dispersed on a substrate, which is shown in FIGS. 4A and 4B. The inset of each of these figures shows optical images of the nanowires under a laser beam. The absorption onsets for the CsPbBr₃ and CsPbI₃ NWs were found to be 521 nm (2.38 eV) and 457 nm (2.71 eV), respectively.

The narrow PL spectrum of CsPbBr₃ (FIG. 4A, dotted line) corresponds to excitonic emission with a small degree of quantum confinement (60 meV blue-shift) due to the narrow wire diameter. A greater degree of confinement was observed for the nanosheets (69 meV) due to an average sheet thickness of only a few unit cells. Temperature-dependent PL of the CsPbBr₃ NWs reveals a small blue-shift (0.035 meV/K) with increasing temperature. While the opposite trend is typically observed, this behavior has been reported for a range of materials, including Pb-doped CsBr crystals as well as closely related cesium metal halide and organometal halide pervoskites. The effect is attributed to the balance between lattice expansion/contraction and electron-phonon coupling; electron-phonon coupling typically dominates band gap behavior and results in a red-shift with increasing temperature. It was previously reported, however, that the lattice term was dominant in CsSnI₃; it is hypothesized that CsPbBr₃ behaves similarly here.

The CsPbI₃ PL spectrum (FIG. 4B, dotted line) consists of two distinct peaks centered at 446 nm (2.78 eV) and 523 nm (2.37 eV), with widths of 115 and 530 meV (fwhm), respectively. The narrow, high-energy peak likely stems from excitonic emission similar to that of CsPbBr₃, but the broad, low-energy peak observed for CsPbI₃ has been attributed previously to the formation of self-trapped excitons (STEs). Exciton self-trapping has been observed for a variety of ionic compounds, including a number of recently studied organometal halide perovskite materials. The temperature-dependent PL of CsPbI₃ NWs was also significantly more complex than that of CsPbBr₃. At low temperatures, only STE emission was observed. Upon heating past 100 K, the excitonic emission peak appears and grows monotonically with temperature. Unlike CsPbBr₃, the excitonic peak red-shifts with increasing temperature, suggesting that a strong electron-phonon coupling contribution dictates band gap behavior. This is consistent with the self-trapping of excitons; increased electron-phonon coupling results in greater lattice distortion in the proximity of the exciton, thereby increasing the probability of trapping.

In some embodiments, a method of fabricating nanowires (e.g., such as a method described herein) may yield cesium lead halide nanowires of a specific halogen that have uniform diameters and/or desirable optical properties. In some embodiments, the method may have a higher yield of nanowires for a specific halogen compared to other halogens. In such a case, cesium lead halide nanowires of a specific halogen (e.g., bromine) may be fabricated. An anion-exchange process can be performed on the CsPbBr₃ nanowires to replace some of all of the bromine with another halogen, such as chlorine or iodine, for example.

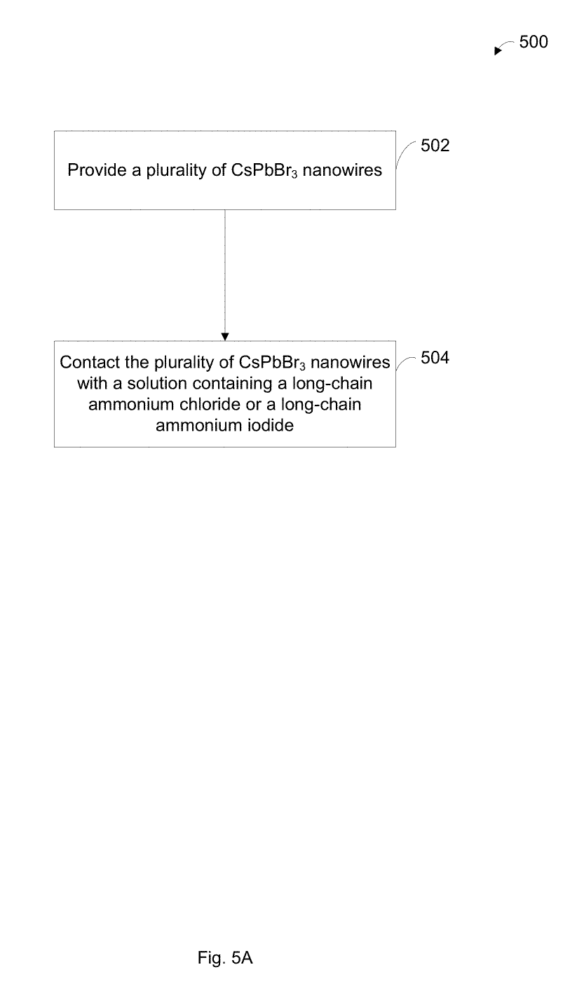

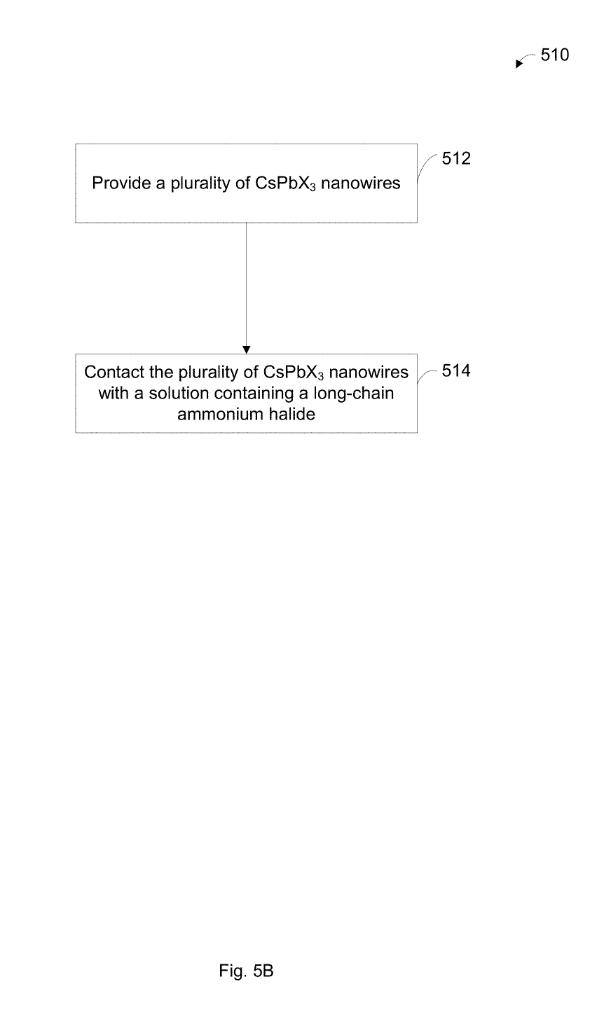

FIGS. 5A and 5B show examples of flow diagrams illustrating an anion-exchange process performed with CsPbBr₃ and CsPbX₃ nanowires. For example, the bromine in a CsPbBr₃ nanowire can be exchanged with another halogen, such as chlorine or iodine. CsPb(Br/Cl)₃ and CsPb(Br/I)₃ nanowires can be formed with such an anion-exchange process.

At block 502 of the method 500 shown in FIG. 5A, a plurality of CsPbBr₃ nanowires is provided. In some embodiments, the CsPbBr₃ nanowires have diameters of about 8 nm to 12 nm, or about 10 nm. In some embodiments, the method 100 shown in FIG. 1 is used to fabricate the plurality of CsPbBr₃ nanowires. In some embodiments, the surfactant used at block 120 of the method 100 to fabricate the plurality of CsPbBr₃ nanowires comprises octylamine.

At block 504, the plurality of CsPbBr₃ nanowires is contacted with a solution including a long-chain ammonium chloride or a long-chain ammonium iodide (i.e., a long-chain ammonium halide). Examples of long-chain ammonium chlorides and iodides include oleylammonium chloride and oleylammonium iodide. Additional examples of long-chain ammonium halides (i.e., chlorides and iodides) include C8 through C24 (C8-C24) linear alkyl ammonium halides and di-, tri-, and tert-alkyl ammonium halides. At least some of the Br in the nanostructure is replaced with Cl or I during an anion-exchange reaction.

In some embodiments, the solvent of the solution comprises a non-polar solvent. In some embodiments, the solvent comprises a C8 though C24 (C8-C24) olefin or octadecene (ODE). In some embodiments, a concentration of the long-chain ammonium chloride or long-chain ammonium iodide in the solution is about 0.1 milligrams per milliliter (mg/mL) to 10 mg/mL or about 0.1 mg/mL to 5 mg/mL. In some embodiments, the plurality of CsPbBr₃ nanowires is contacted with the solution for about 1 minute to 7200 minutes, about 60 minutes to 5760 minutes, or about 240 minutes to 4320 minutes. In some embodiments, block 504 is performed in an inert gas environment. In some embodiments, the solution is at a temperature of about 40° C. to 80° C.

The length of time for which the plurality of CsPbBr₃ nanowires is contacted with the solution determines, in part, the degree to which Br is replaced with Cl or I in the anion exchange process. Generally, the longer the period of time that the nanowire is contacted with the solution, the greater the degree to which the anion exchange process occurs with Br being replaced with Cl or I. The concentration of the long-chain ammonium chloride or long-chain ammonium iodide in the solution determines, in part, the degree to which Br is replaced with Cl or I in the anion exchange process. Generally, the higher the concentration of the long-chain ammonium chloride or long-chain ammonium iodide in the solution, the faster the anion exchange (i.e., Br being replaced with Cl or I) will occur. The concentration of the long-chain ammonium chloride or long-chain ammonium iodide in the solution is specified so that the anion exchange process does not occur too quickly and damage the morphology of the nanowires. For example, if Br is completely replaced with Cl or I in 10 minutes or less, the morphology of the nanowires may be damaged. In some embodiments, lower concentrations of the long-chain ammonium chloride or long-chain ammonium iodide in the solution and short exposure times may be used to generate a composition of the nanowires in which a small amount of Br is exchanged with Cl or I.

In some embodiments, nanowires of the plurality of nanowires have the same morphology and crystal structure before and after block 504. For example, in some embodiments, a CsPbBr₃ nanowire has an orthorhombic crystal structure before block 504 and an orthorhombic crystal structure after at least some of the bromine has been exchanged with chlorine or iodine after block 504. In some embodiments, nanowires of the plurality of nanowires comprise or consist of single crystals.

In some embodiments to the method 500 shown in FIG. 5A, cesium lead halide nanowires that are not necessarily CsPbBr₃ (e.g., the cesium lead halide could be CsPbCl₃ or CsPbI₃) are provided. As shown in the method 510 shown in FIG. 5B, in such a method, a plurality of nanowires comprising CsPbX₃ is provided at block 512. X comprises a first halide selected from a group consisting of chlorine (Cl), bromine (Br), and iodine (I). At block 514, the plurality of nanowires is contacted with a solution including a long-chain ammonium halide including a second halide. The second halide is a different halide than the first halide and is selected from a group consisting of Cl, Br, and I. At least some of the first halide of the plurality of nanowires is replaced with the second halide.

The methods 500 and 510 described above with reference to FIGS. 5A and 5B can be used with any of the methods used to fabricate nanowires or nanosheets described herein.

Anion exchange processes were performed on CsPbBr₃ NWs using embodiments of the method 500 shown in FIG. 5A to synthesize composition tunable and luminescent mixed-halide CsPbX₃ (X=Cl, Br, I) NWs. To fabricate the NWs, a Cs-oleate solution was prepared by loading 0.2 g Cs₂CO₃ and 0.6 mL oleic acid into a flask along with 7.5 mL octadecene. The solution was then degassed and dried under vacuum at 120° C. (the temperatures here refer to the temperature of the oil bath) for 20 minutes and then heated under N₂ to 150° C. until all Cs₂CO₃ reacted with oleic acid.

CsPbBr₃ NWs were fabricated by loading 5 mL octadecene and 0.2 mmol PbX₂ into a flask and degassing under vacuum for 20 minutes at 120° C. 0.8 mL dried octylamine and 0.8 mL dried oleylamine were injected at 120° C. under N₂ successively. After the injection of octylamine, the solution gradually turned a bit milky, and with the injection of oleylamine, the solution turned clear. The temperature was then raised to 135° C. The solution was stirred for 20 minutes and became opaque white. The solution was kept at 135° C., and 0.7 mL of as-prepared Cs-oleate solution was injected. After 40 minutes to 60 minutes, the reaction mixture was cooled by a water bath. The NWs were isolated by centrifugation at 6000 rpm for 5 minutes and washed once with hexane. The precipitated NWs were then re-dispersed in hexane/toluene. The NWs had uniform diameters of 8 nm to 12 nm. The NWs had lengths of a few microns.

The anion exchange reaction was performed under air-free conditions using Schlenk techniques. PbX₂ or an oleylammonium halide was used as the anion source and mixed with octadecene (5 mL) in a flask and kept under vacuum at 100° C. for 20 minutes. Surfactants such as oleic acid, oleylamine, and mixtures thereof were injected at 100° C. under N₂ flow. After complete dissolution of the anion source, the temperature was lowered to 40° C. to 80° C. and CsPbBr₃ NWs (0.01 mmol to 0.025 mmol) dispersed in hexane/toluene were injected to initiate the anion-exchange reaction. After reaction, the NWs were isolated by centrifugation at 6000 rpm for 5 minutes and washed once with hexane. The obtained precipitated NWs were re-dispersed in hexane/toluene for further analysis.

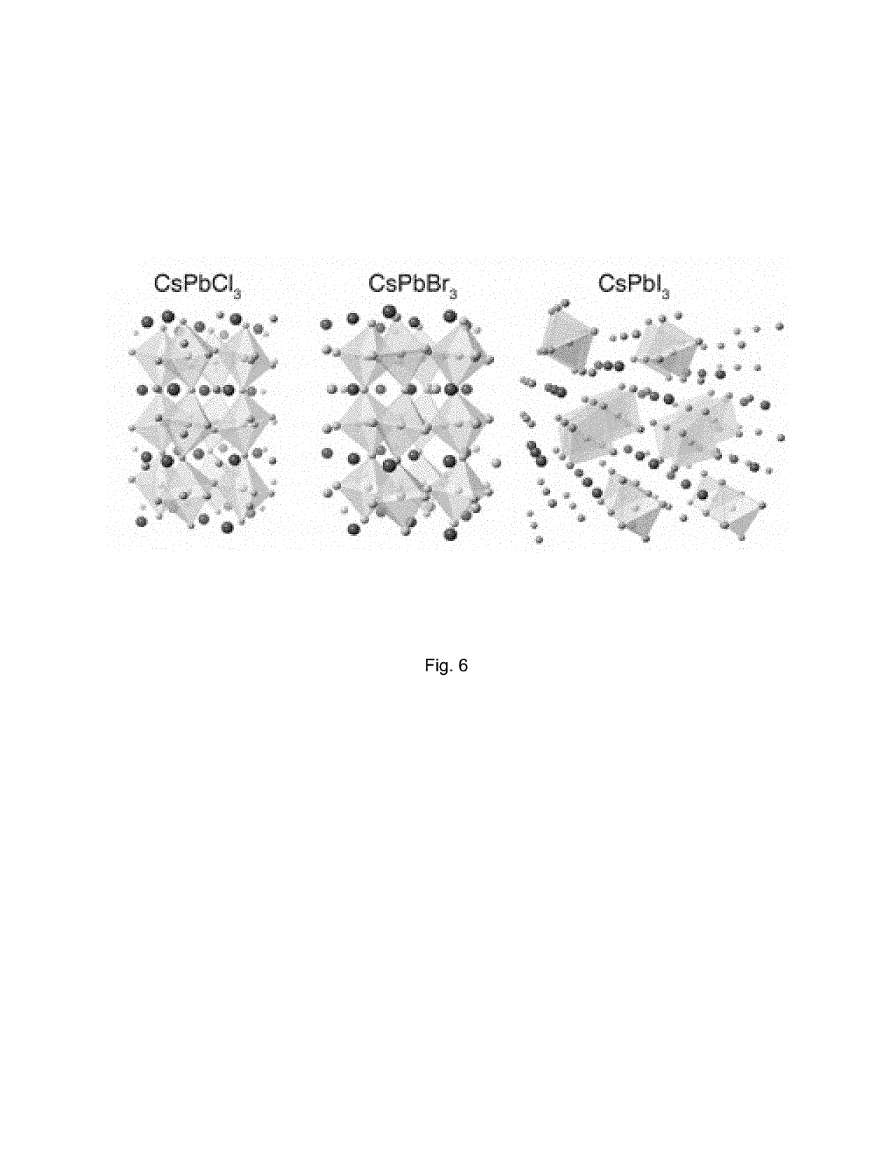

As shown in FIG. 6, pure orthorhombic CsPbI₃ has a different crystal structure than orthorhombic CsPbCl₃ or CsPbBr₃. Orthorhombic CsPbI₃ does not have a 3D corner-sharing PbI₆ network but instead contains ribbons of edge-connected PbI₆ octahedra and thus has only quasi-2D connectivity. Nevertheless, the crystal structure of CsPbBr₃ NWs remained corner-sharing orthorhombic after exchange with I- or Cl-anions, with only a slight shift in the XRD pattern. This is probably due to the rigidity of the cationic framework that leads to the topotaxial nature of the exchange. The shifts are explained by lattice expansion or contraction caused by the substitution of the larger I-ion or smaller Cl-ion, respectively. A slight change in XRD peak profile during anion exchange was also observed. More specifically, a simulated pattern was used to fit the experimental XRD pattern of the Br—I alloy, and the calculated lattice parameters show an anisotropic expansion behavior compared to the lattice parameters of the orthorhombic CsPbBr₃, indicating that a slight anisotropic distortion occurred within the lattice during anion exchange.

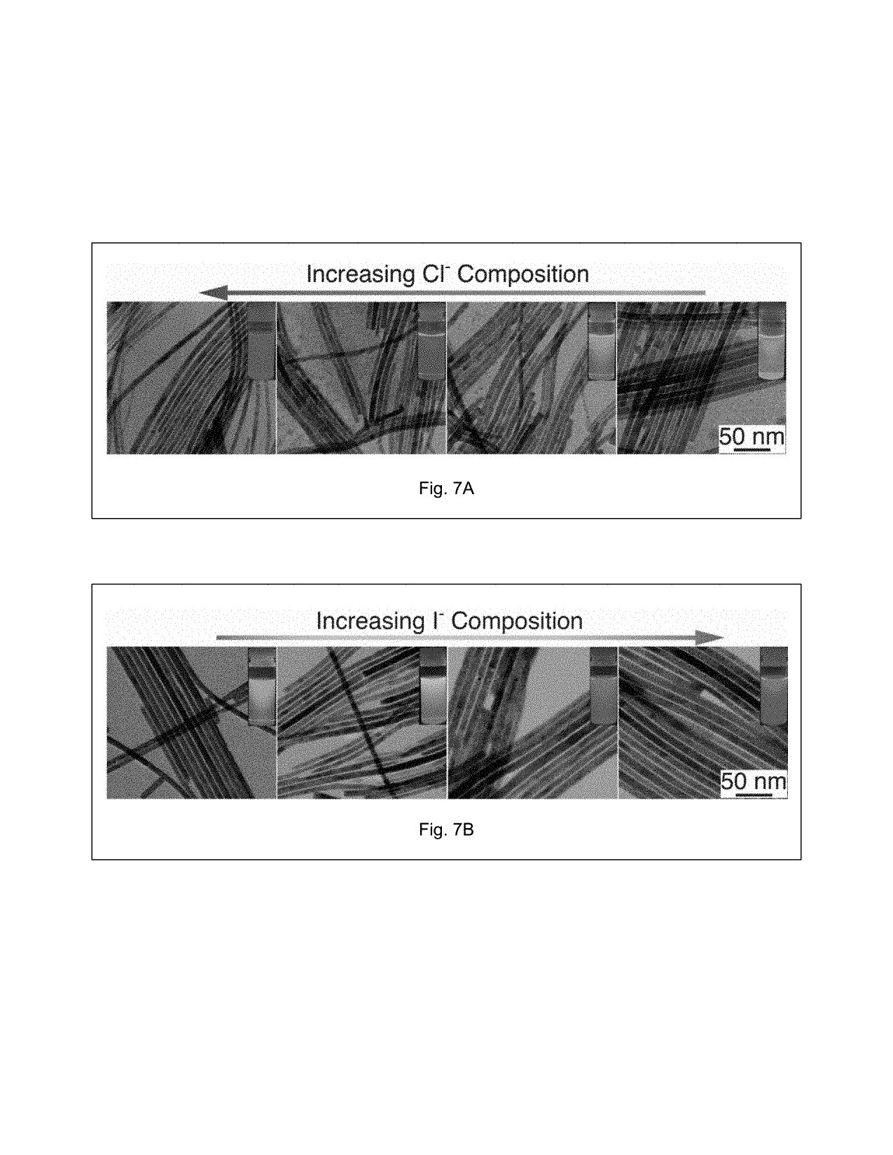

The size and shape of the NWs was also preserved in both the Br—I and Br—Cl exchanges as shown in FIGS. 7A and 7B. High-resolution transmission electron microscopy (HRTEM) images of the Br—I and Br—Cl exchange products clearly showed the single-crystalline nature of the exchanged NWs, as the absence of epitaxial interfaces and grain boundaries indicated the formation of homogenous alloy structures. The elemental mapping of the exchanged samples was obtained using energy dispersive X-ray spectroscopy (EDS) and also shows a uniform distribution of Cl/I along the whole NWs. For the iodine-exchanged CsPbBr₃ NWs, the I⁻ percentage was observed to be about 92% with EDS for the NWs that were anion-exchanged the most. The distinct crystal structures between orthorhombic CsPbBr₃ and CsPbI₃ may be the reason for the self-limiting behavior of the Br—I exchange. For the chlorine-exchanged CsPbBr₃ NWs, the BP is estimated to be completely exchanged with Cl⁻ for the NWs that were anion-exchanged the most.

The CsPbBr₃ NWs anion-exchanged with chlorine and iodine had a tunable photoluminescence spanning over nearly the entire visible spectral region (409 nm to 680 nm). The as-grown CsPbBr₃ NWs had an emission peak (UV excitation, λ=365 nm) at 519 nm, which gradually red shifted with increased I-content to reach a final value of 680 nm. When the I-precursor was replaced with the Cl-precursor, the photoluminescence peaks of the CsPbBr₃ NWs blue shifted to shorter wavelengths to reach a shortest wavelength of 409 nm.

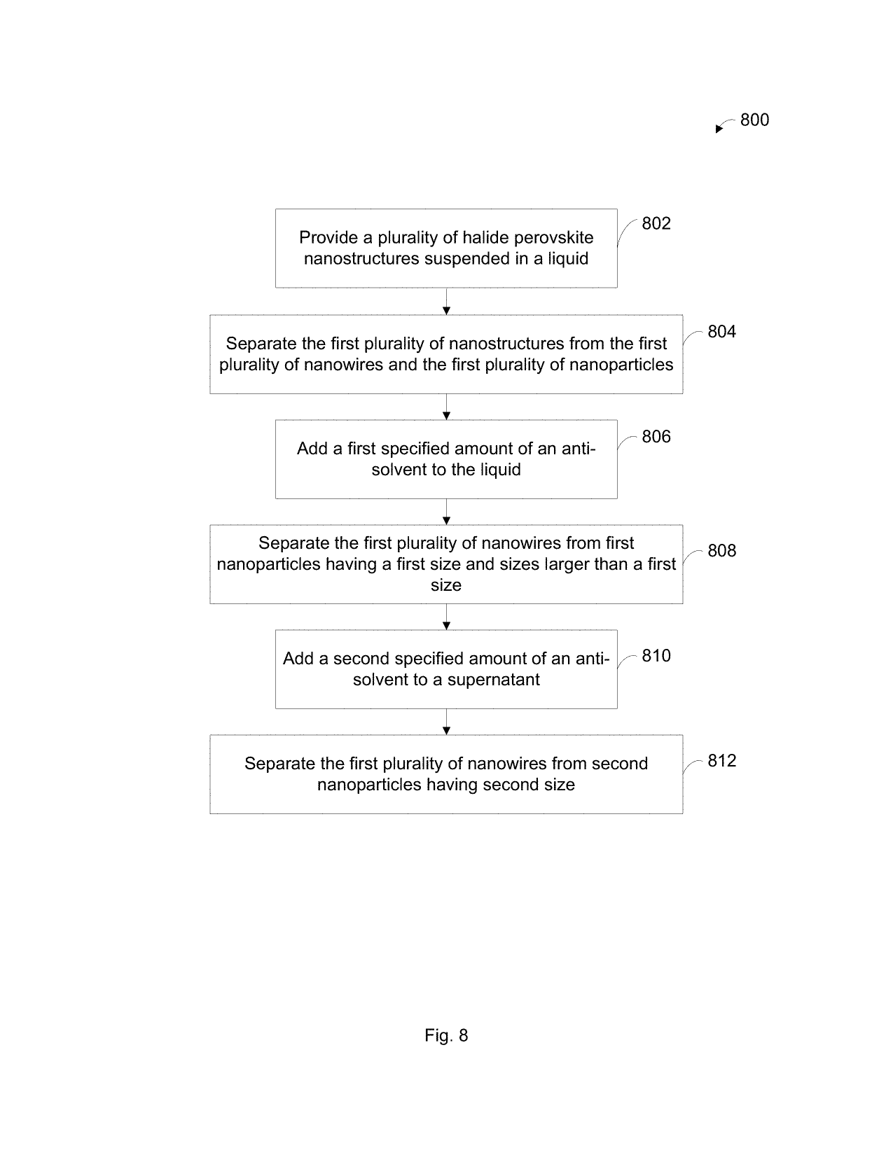

FIG. 8 shows an example of a flow diagram illustrating process for separating small-diameter halide perovskite nanowires from other halide perovskite nanostructures. In some embodiments, the small-diameter halide perovskite nanowires have a diameter of about 2 nm to 3 nm.

At block 802 of the method 800 shown in FIG. 8, a plurality of halide perovskite nanostructures suspended in a liquid is provided. Halide perovskite nanostructures may be dispersed or suspended in a non-polar liquid/solvent, and the ligands on the halide perovskite nanostructures make the nanostructures soluble in a non-polar liquid.

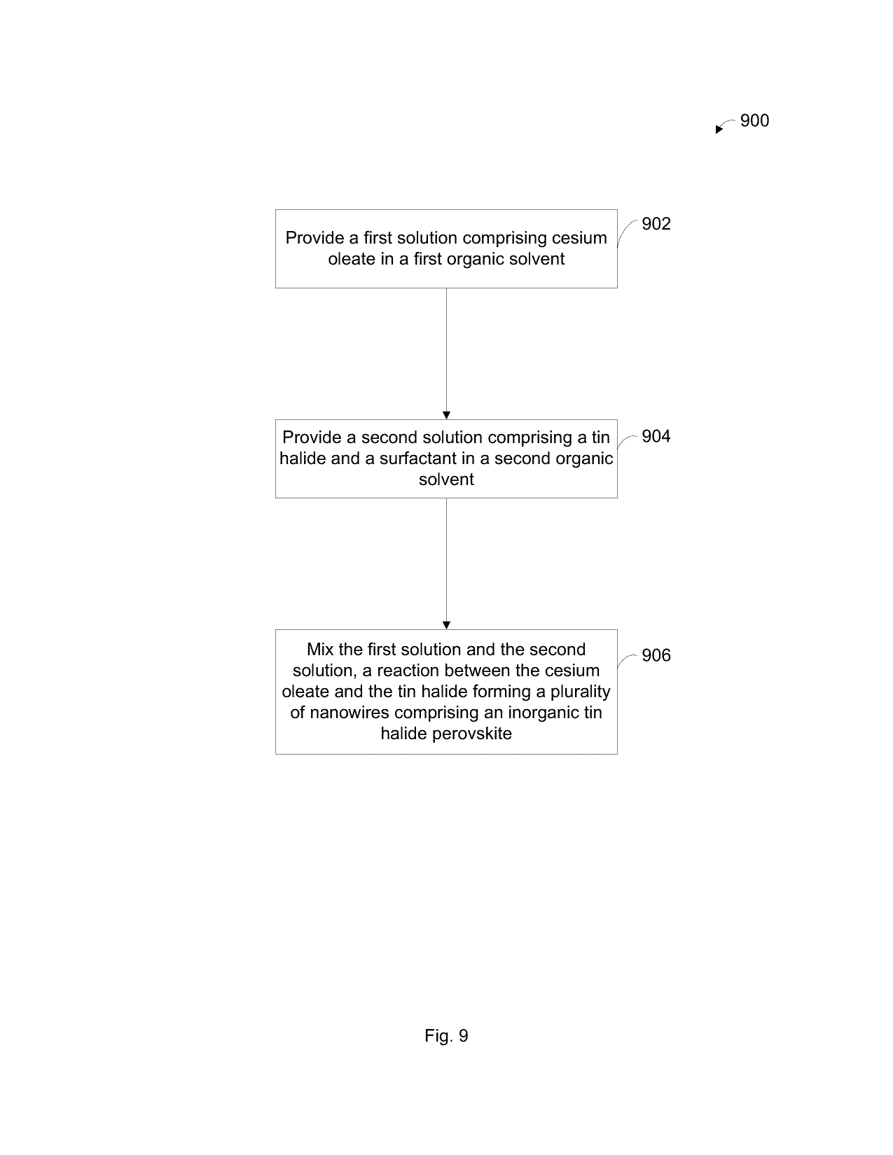

In some embodiments, the plurality of halide perovskite nanostructures is a plurality of inorganic halide perovskite nanostructures. In some embodiments, the plurality of halide perovskite nanostructures comprises a plurality of larger-sized halide perovskite nanostructures, the plurality of halide perovskite nanowires, and a first plurality of halide perovskite nanoparticles. The plurality of halide perovskite nanowires includes a first plurality of halide perovskite nanowires, with nanowires of the first plurality of halide perovskite nanowires having diameters of 2 nm to 3 nm. In some embodiments, the plurality of halide perovskite nanostructures comprises the plurality of nanowires (e.g., nanowires having diameters of about 8 nm to 10 nm), nanoplates, and nanoparticles. For example, the halide perovskite nanostructures may be fabricated using embodiments of the method 100 shown in FIG. 1 or embodiments of the method 900 (described below) shown in FIG. 9.

Nanowires of the first plurality of halide perovskite nanowires are thin or small-diameter halide perovskite nanowires. The ligands used in the fabrication process determine in part the diameters of the halide perovskite nanowires generated. For example, using dodecylamine, oleylamine, and oleic acid surfactants when fabricating halide perovskite nanowires can generate nanowires having a diameter of about 2 nm to 3 nm. In some embodiments, other acids, such as hexanoic acid ligands or octanoic acid, are used instead of oleic acid. In some embodiments, decylamine is used instead of dodecylamine.

At block 804, the first plurality of nanostructures is separated from the first plurality of nanowires and the first plurality of nanoparticles. Nanostructures of the first plurality of nanostructures having a larger size (e.g., diameter) than the first plurality of nanowires and the first plurality of nanoparticles means that they have more mass and have less colloidal stability. In some embodiments, the nanowires of the plurality of nanowires having a larger size are also removed in this operation.

In some embodiments, the separation is performed with a centrifuge. A centrifuge applies an effective gravitational force to the liquid including the plurality of nanostructures. Under a gravitational force (or an effective gravitational force), the size and density of a nanostructure and the rate at which the nanostructure separates from a plurality of nanostructures are correlated; nanostructures having a larger size and density separate more quick from other nanostructures having a smaller size and/or density.

At block 806, a first specified amount of an anti-solvent is added to the liquid in which the first plurality of nanowires and the first plurality of nanoparticles are suspended. Again, the halide perovskite nanowires and nanoparticles may be dispersed or suspended in a non-polar liquid/solvent, and the ligands on the halide perovskite nanowires and nanoparticles make them soluble in a non-polar liquid. The anti-solvent decreases the solubility of the nanowires and nanoparticles in the liquid. In some embodiments, the anti-solvent is a polar solvent. In some embodiments, the anti-solvent does not dissolve the halide perovskite nanowires or nanoparticles.

In some embodiments, the anti-solvent has a polarity index of about 4 to 5. The polarity index is a measure of the polarity of the solute-solvent interactions. In some embodiments, the polarity index of the anti-solvent should not be higher than about 5 because the anti-solvent might then damage the halide perovskite nanowires. Also, if the polarity index of the anti-solvent is too high, adding a small first specified amount of the anti-solvent to the liquid will decrease the solubility of the halide perovskite nanowires to a degree such that the halide perovskite nanowires cannot be separated from the halide perovskite nanoparticles. In some embodiments, the polarity index of the anti-solvent should not be lower than about 4 because the solubility of the halide perovskite nanoparticles would not be decreased enough to separate them from the halide perovskite nanowires after adding a first specified amount of the anti-solvent to the liquid. In some embodiments, the anti-solvent is selected from a group consisting of ethyl acetate (polarity index=4.4), methyl ethyl ketone (polarity index=4.7), and methyl isobutyl ketone (polarity index=4.2).

At block 808, the first plurality of halide perovskite nanowires is separated from first nanoparticles of the first plurality of nanoparticles. The first nanoparticles have a first size (e.g., diameter) and sizes larger than the first size. In some embodiments, the first nanoparticles have more mass than nanowires of the first plurality of halide perovskite nanowires. In some embodiments, the separation is performed with a centrifuge. The first nanoparticles having more mass than nanowires of the first plurality of halide perovskite nanowires means that they will separate from the nanowires in the centrifuge.

For example, the halide perovskite nanowires and nanoparticles in the liquid may be centrifuged for about 2 minutes to 8 minutes, or about 5 minutes, at about 3000 rpm to 9000 rpm, or about 6000 rpm. The halide perovskite nanoparticles having the first size and sizes larger than the first size gather at the bottom of a centrifuge chamber after centrifugation. The halide perovskite nanowires remain suspended in the supernatant. In some embodiments, nanoparticles having a size smaller than the first size remain suspended in the supernatant. If some halide perovskite nanoparticles remain suspended in the supernatant, the centrifugation process may be repeated one to five more times.

For example, as shown in FIG. 8, at block 810, a second specified amount of an anti-solvent is added to a supernatant including the halide perovskite nanowires and nanoparticles, with the nanoparticles being smaller than the nanoparticles having the first size from block 808. The second specified amount of the anti-solvent is larger than the first specified amount of the anti-solvent. This larger amount of the anti-solvent will cause halide perovskite nanoparticles having a smaller size than the first size of first nanoparticles to be removed from the liquid.

At block 812, the first plurality of nanowires is separated from second nanoparticles of the first plurality of nanoparticles. The second nanoparticles have a second size, with the second size being smaller than the first size. In some embodiments, the separation is performed with a centrifuge. In some embodiments, the separation process at block 812 is similar to or the same as the separation process at block 808.

An embodiment of the method 800 shown in FIG. 8 was used to purify or separate highly uniform single-crystalline CsPbBr₃ NWs with diameters down to 2.2±0.2 nm. Large blue shifted UV-vis absorption and photoluminescence (PL) spectra were observed. The ultrathin NWs had bright photoluminescence with about 30% photoluminescence quantum yield (PLQY) after purification and a surface treatment. The diffraction pattern from small angle X-ray scattering (SAXS) reflects the periodic packing of the ultrathin NWs, demonstrates the narrow size distribution of the NWs, and shows the deep intercalation of the surfactants. Through anion-exchange reactions, the halide composition of the ultrathin NWs can be readily controlled with the preservation of the ultrathin NW morphology.

Colloidal synthesis methods were used to fabricate ultrathin CsPbBr₃ NWs. 5 mL ODE, 0.2 mmol PbBr₂, and 4.3 g 1-dodecylamine were loaded into a flask and degassed under vacuum for 20 minutes at 100° C. 0.8 mL dried oleylamine and 0.2 mL dried oleic acid were injected at 160° C. under Ar successively. The solution was kept at 160° C. for 20 minutes for full dissolution of the precursor. Afterwards, 0.7 mL of Cs-oleate solution was quickly injected. After 20 minutes, the reaction mixture was cooled by a water bath.

The yield of the ultrathin NWs was generally low (e.g., only about several percent). The stepwise purification method was used to improve the purity of the sample to over 90%. By using different volumes of ethyl acetate (EA) as the anti-solvent, ultrathin NWs could gradually be separated from other impurities and larger NWs.

After the fabrication of the CsPbBr₃ NWs, the product from the reaction was centrifuged at 6000 rpm for 5 minutes. The supernatant from the centrifugation was kept for further purification. 20 mL ethyl acetate was added to the supernatant as an anti-solvent (the volume ratio of the original supernatant to anti-solvent was about 1:4), and the clear supernatant solution immediately became cloudy. Afterwards, the solution was centrifuged at 6000 rpm for 5 min, and the supernatant was kept for further purification. Three similar operations were performed by adding extra ethyl acetate to the purified supernatant with an overall volume ratio of the original supernatant to anti-solvent being about 1:7, 1:10, and 1:35 in each successive operation.

To achieve wide chemical tunability, an anion-exchange process can be applied to the ultrathin CsPbBr₃ NWs in which BP anions are replaced with either Cl⁻ or I⁻ ions. Halide exchange reactions were carried out at room temperature using PbX₂ (X=Cl, I) as precursors. For example, a stock solution of anhydrous toluene (5 mL), PbX₂ (0.188 mmol, X=Cl or I), OA (0.5 mL), and OAm (0.5 mL) was made. 0.05 mL to 0.6 mL of 10% diluted precursor solution was added to the purified ultrathin CsPbBr₃ nanowire solution at room temperature.

The blue emission from the ultrathin CsPbBr₃ NWs can be tuned through purple to red emission with different conversion degree. After the anion-exchange, the morphology of the ultrathin wires was largely preserved. The slight size expansion (Br—I exchange) and contraction (Br—Cl exchange) can also be observed from TEM images.

When an excess amount of anion-exchange precursor is added to the CsPbBr₃ system, a competitive reaction mechanism other than anion-exchange reaction can be observed. This reaction mechanism damages to the ultrathin NWs and forms nanocubes and irregular nanocrystals. Coordinating an excessive amount of ligands on the ultrathin wires may gradually etch and dissolve the NWs, subsequently leading to formation thermodynamically more favorable morphologies, such as cubes or irregular crystals, for example. This competitive reaction can be largely suppressed by reducing the amount of the precursor. However, occasionally asymmetric red emission tails observed in the PL emission spectra imply that a small portion of the ultrathin NWs are still damaged during the anion-exchange process.

FIG. 9 shows an example of a flow diagram illustrating a fabrication process for inorganic tin halide perovskite nanowires. Some embodiments of the method 900 shown in FIG. 9 are a solution-phase method. In some embodiments of the method 900, nanosheets are also generated. At block 902 of the method 900, a first solution comprising cesium oleate in a first organic solvent is provided. The first solution of cesium oleate may be formed, for example, by mixing cesium carbonate and oleic acid in the first organic solvent. Other cesium/rubidium solutions also can be used. For example, in some embodiments, the first solution can be formed by mixing cesium carbonate and an organic acid (e.g., octanoic acid (CH₃(CH₂)₆COOH) or heptadecanoic acid (CH₃(CH₂)₁₅COOH)) or an organic amine (e.g., octylamine (CH₃(CH₂)₆CH₂NH₂), decylamine (CH₃(CH₂)₆CH₂NH₂), or oleylamine (CH₃(CH₂)₇CH═CH(CH₂)₇CH₂NH₂)). The first organic solvent may comprise a non-coordinating solvent, such as a long chain olefin, for example. In some embodiments, the first solvent comprises octadecene (ODE). In some embodiments, block 902 is performed in an inert gas environment.

At block 904, a second solution comprising a tin halide and a surfactant in a second organic solvent is provided. The halide is selected from a group consisting of chlorine, bromine, and iodine. The surfactant may comprise an amine or a phosphine. For example, in some embodiments, the surfactant comprises a surfactant selected from a group consisting of octylamine, oleylamine, oleic acid, and combinations thereof. Other amines with long carbon chains (e.g., octadecylamine) may also be used. In some embodiments, the surfactant comprises trioctylphosphine. The second organic solvent may comprise a non-coordinating solvent or a coordinating solvent. In some embodiments, the second organic solvent comprises ODE. In some embodiments, the second organic solvent comprises oleylamine. In some embodiments, at block 904 a second solution comprising a tin halide and a surfactant and no second organic solvent is provided. For example, SnI₂ in trioctylphosphine may be provided. In some embodiments, block 904 is performed in an inert gas environment.

At block 906, the first solution and the second solution are mixed. For example, the first solution may be poured or injected into the second solution. A reaction between the cesium oleate and the tin halide forms a nanowire in some embodiments and a nanoplate in some embodiments comprising an inorganic tin halide perovskite. In some embodiments, the mixture is held at about 130° C. to 250° C. for about 5 minutes to 20 hours. In some embodiments, block 906 is performed in an inert gas environment. In some embodiments, a plurality of nanowires formed at block 906 comprises ABX₃, wherein A is Cs, wherein B is Sn, and wherein X is Cl, Br, or I. The method 900 may also be used to fabricate tin halide perovskite nanobelts/nanoribbons and nanosheets. In some embodiments of the method 900, no trioctylphosphine is present. In some embodiments of the method 900, all operations are performed in an inert gas atmosphere with little to no water being present.

In some embodiments, a fabrication process for inorganic tin halide perovskite nanowires and nanoplates includes providing a first solution comprising a cesium salt dissolved in organic amines and other organic solvents, providing a second solution comprising a tin halide and a surfactant in an organic solvent, and mixing the first solution and the second solution, a reaction between the solvated cesium precursor and the tin halide precursor forming a plurality of nanowires or nanoplates comprising an inorganic tin halide perovskite.

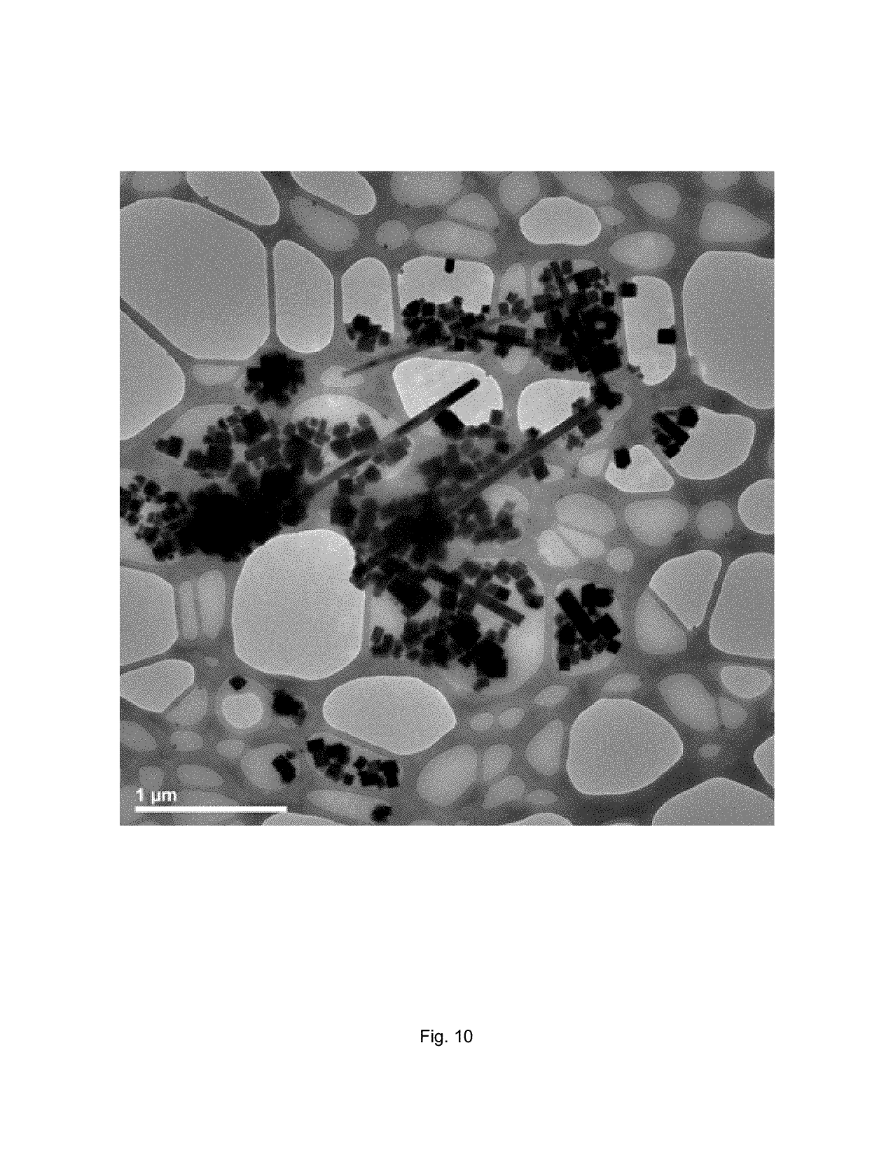

FIG. 10 shows a micrograph of CsSnI₃ nanowires mixed with CsSnI₃ nanoparticles. The CsSnI₃ nanowires and nanoparticles were fabricated using an embodiment of the method 900 shown in FIG. 9.

In some embodiments, a method of fabricating inorganic tin halide perovskite nanowires includes dissolving cesium carbonate in octanoic acid and octylamine. In some embodiments, tin is dissolved in trioctylphosphine. The tin dissolved in trioctylphosphine is injected in the cesium solution.

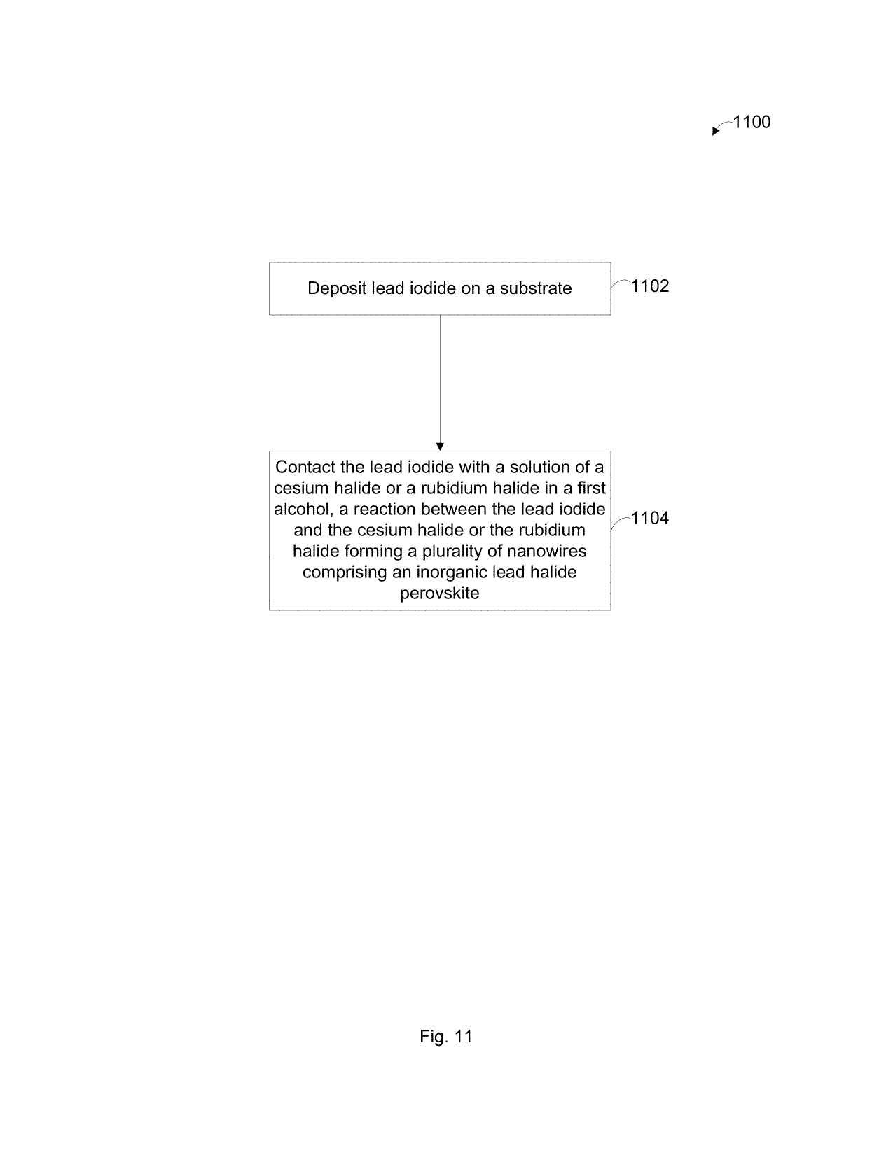

FIG. 11 shows an example of a flow diagram illustrating a fabrication process for inorganic lead halide perovskite nanowires. In some embodiments of the method 1100 shown in FIG. 11, a substrate is used in the fabrication process (i.e., a substrate based fabrication process). In some embodiments of the method 1100, nanosheets are also generated. At block 1102, lead iodide is deposited on a substrate. In some embodiments, another lead halide (e.g., lead chloride in the form of a lead chloride layer or a lead chloride film) is deposited on the substrate.

In some embodiments, depositing lead iodide on a substrate comprises depositing a solution of lead iodide in a solvent on the substrate and then evaporating the solvent. Depositing the solution on the substrate may be performed with a spin coating process, for example. In some embodiments, the solvent comprises a solvent selected from a group consisting of dimethylformamide (DMF) and dimethyl sulfoxide (DMSO). In some embodiments, evaporating the solvent comprises annealing the substrate at about 70° C. to 100° C. for about 10 minutes to 20 minutes.

In some embodiments, the substrate comprises a material that the solution of lead iodide in a solvent wets. In some embodiments, the substrate comprises a glass. In some embodiments, the glass is oxygen plasma treated. An oxygen plasma treatment may clean the glass and improve its wetting properties (i.e., decrease the hydrophobicity of the glass and reduce the contact angle between the glass and the solution). In some embodiments, a polymer may be disposed on a surface of the substrate. The lead iodide solution may wet the polymer. For example, in some embodiments, the polymer comprises a hydrophilic polymer. In some embodiments, the polymer comprises a polymer selected from a group consisting of poly(3,4-ethylenedioxythiophene) (PEDOT), poly(3,4-ethylenedioxythiophene) polystyrene sulfonate (PEDOT:PSS), and polyaniline.

At block 1104, the lead iodide is contacted with a solution of a cesium halide or a rubidium halide in a first alcohol. In some embodiments, the lead iodide is contacted with the solution of the cesium halide or the rubidium halide in the first alcohol at about 20° C. to 80° C. for about 6 hours to 18 hours. For example, the substrate with the lead iodide disposed thereon may be immersed in a solution of the cesium halide or the rubidium halide in the first alcohol. The halide of the cesium halide is a halide selected from a group consisting of chlorine, bromine, and iodine. A reaction between the lead iodide and the cesium halide or the rubidium halide forms a plurality of nanowires comprising an inorganic lead halide perovskite. The first alcohol may comprise a short chain alcohol. For example, in some embodiments, the first alcohol comprises methyl alcohol or ethyl alcohol. In some embodiments, the plurality of nanowires comprises ABX₃, wherein A is Cs or Rb, wherein B is Pb, and wherein X is Cl, Br, or I. In some embodiments, block 220 is performed in an inert gas atmosphere.

In some embodiments, after block 1104, the plurality of nanowires is washed with a second alcohol. The second alcohol is used to clean the plurality of nanowire without damaging the. The second alcohol may be an alcohol that is less polar than methyl alcohol. For example, in some embodiments, the second alcohol comprises isopropyl alcohol.

Is some embodiments of the method 1100, tin iodide is deposited on the substrate at block 1102. Using tin iodide in the method 1100 would form inorganic tin halide perovskite nanowires.

An embodiment of the method 1100 shown in FIG. 11 was used to synthesize single crystal CsPbX₃ nanowires (X=Br, Cl). The method included dipping a PbI₂ thin film into a CsX-methanol solution with mild heating. Briefly, approximately 1×1 cm glass substrates were cut and washed sequentially with acetone, isopropanol, and deionized water. Cleaned substrates were then 02 plasma treated for 10 minutes, followed by spin coating with PEDOT:PSS at 3000 rpm for 30 seconds. Afterward, the coated substrates were annealed at 150° C. for 15 minutes.

460 mg PbI₂ was dissolved in 1 mL anhydrous dimethylformide (DMF) and stirred at 70° C. overnight before further use. The PbI₂ solution was spin coated onto the PEDOT:PSS-coated glass substrates at 1000 rpm for 120 seconds and then annealed at 100° C. for 15 minutes. The PbI₂ film was submerged in a glass vial with 8 mg/mL CsBr solution in methanol, with the PbI₂ side facing up. The capped reaction vial was heated at 50° C. for 12 hours, and the substrate was removed and washed in anhydrous isopropanol for 30 seconds. The sample was then dried by heating to 50° C. for 5 minutes. For the synthesis of CsPbCl₃ (or CsPbI₃) nanowires, the CsBr-methanol solution was replaced with a 6 mg/mL CsCl-methanol (or 4 mg/mL CsI-methanol) solution. The entire growth process was carried out in a nitrogen-filled glove box.

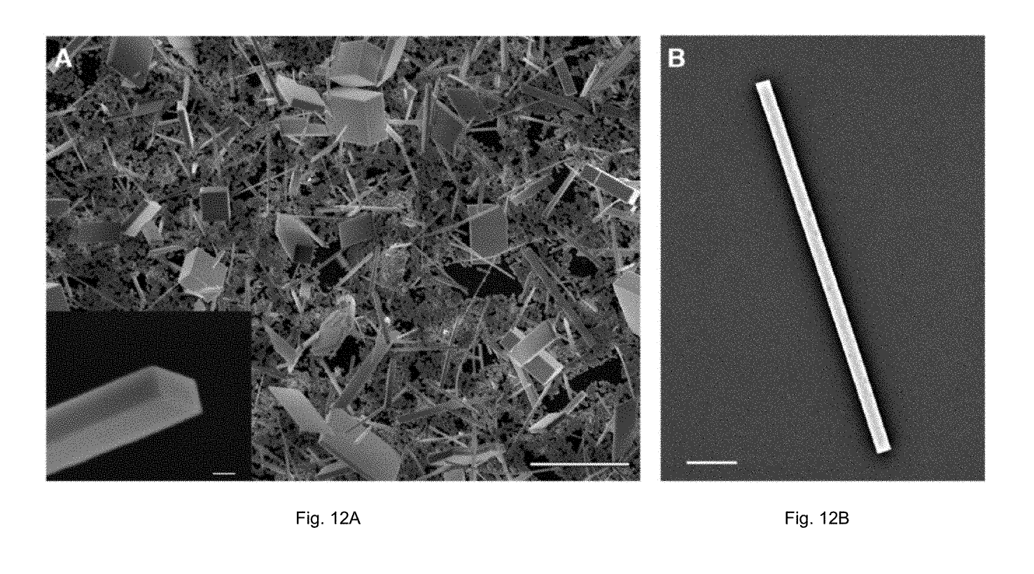

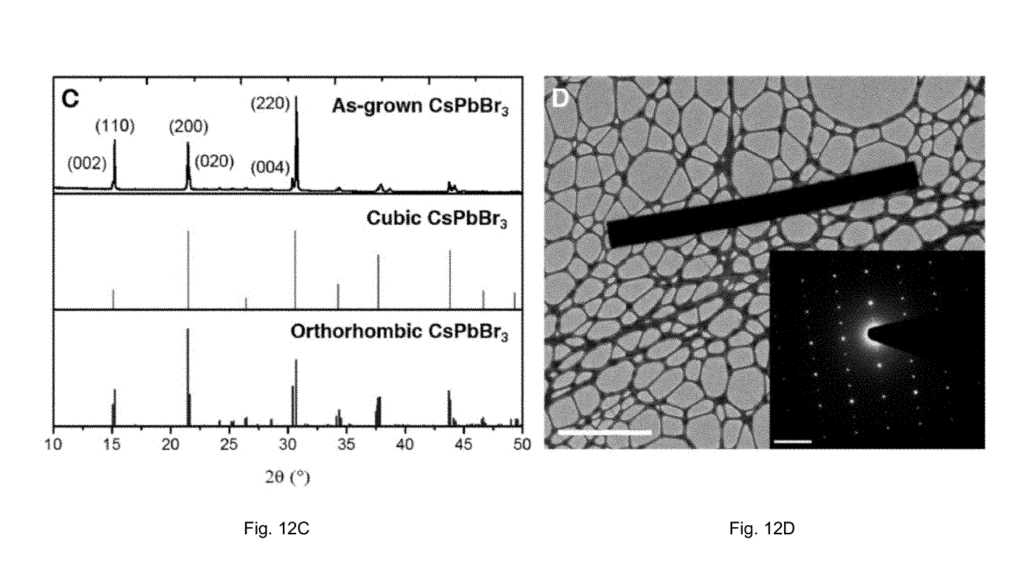

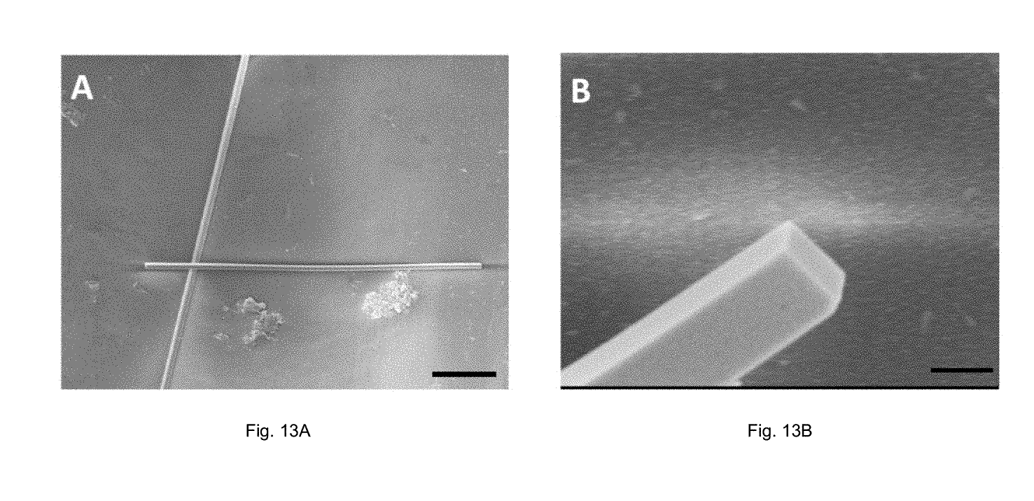

FIGS. 12A-12D show the results of the structural characterization of CsPbBr₃ nanowires. FIG. 12A shows SEM images of CsPbBr₃ nanowires and nanosheets grown from PbI₂ in a methanolic solution of 8 mg/mL CsBr at 50° C. for 12 hours. The scale bar is 10 microns. An SEM image of the rectangular end facet of a nanowire is shown in the inset. The scale bar is 500 nm. FIG. 12B shows a single CsPbBr₃ nanowire isolated on a quartz substrate with a 5 nm Au sputter coat. The scale bar is 1 micron. FIG. 12C shows XRD pattern of as-grown CsPbBr₃ with the standard XRD patterns of cubic and orthorhombic CsPbBr₃. FIG. 12D shows a TEM image of an individual nanowire. The scale bar is 5 microns. A selected-area electron diffraction (SAED) pattern from the same nanowire is shown in the inset and indicates a high degree of crystallinity. The scale bar is 2 nm⁻¹.

From the scanning electron microscopy (SEM) images shown in FIG. 12A, a range of CsPbBr₃ nanoscale morphologies were produced during the 12 hour reaction including nanowires, nanocrystals, and nanosheets. The nanowires range in length from 2 microns to 40 microns and in width from 0.2 microns to 2.3 microns, placing them in an ideal size regime for photonic nanowire lasing. The majority of nanowires were found to have rectangular cross sections (FIG. 12A, inset) with strongly wire-dependent height-to-width ratios. In order to select and study the nanowires independently from the surrounding growth substrate, nanowires were transferred to a separate substrate via micromanipulation (FIG. 12B), and selected based on the presence of clean, well-formed facets, which are important for efficient emission confinement and waveguiding.

The elemental composition and atomic structure of the nanowires were quantified to ensure they conformed to the expected, room-temperature orthorhombic phase of CsPbBr₃. This was important as the reaction mixture contained a small amount of iodide from the initial PbI₂ film, making the chance of a Br—I alloy non-negligible. The X-ray diffraction (XRD) pattern of the CsPbBr₃ growth substrate shows strong diffraction peaks which can be assigned to the pure orthorhombic crystal structure (space group Pbnm), and does not contain impurity peaks from either the PbI₂ or CsBr starting materials (FIG. 12C). The clear splitting of the narrow (002) and (110) peaks further indicate that the as-grown CsPbBr₃ is of the room-temperature orthorhombic phase and comprised of large, crystalline domains. The small peaks from 24° to 29° are also characteristic of the room temperature phase. The nanowire composition was determined by energy-dispersive X-ray spectroscopy and indicated the presence of Cs, Pb, and Br in a 1.1:1.0:2.7 ratio, in close agreement with the CsPbBr₃ phase. The absence of iodide was also confirmed, verifying the compositional purity of the nanowires. The crystal structure of the nanowires was determined through selected area electron diffraction (SAED) as shown in FIG. 12D. The SAED pattern shown in the inset indicates that the nanowires are single crystalline and may be indexed to the [110] zone axis of the orthorhombic phase of CsPbBr₃ in agreement with the XRD pattern. According to the SAED pattern, the nanowire growth direction was also indexed to the [002] direction of the orthorhombic phase of CsPbBr₃.

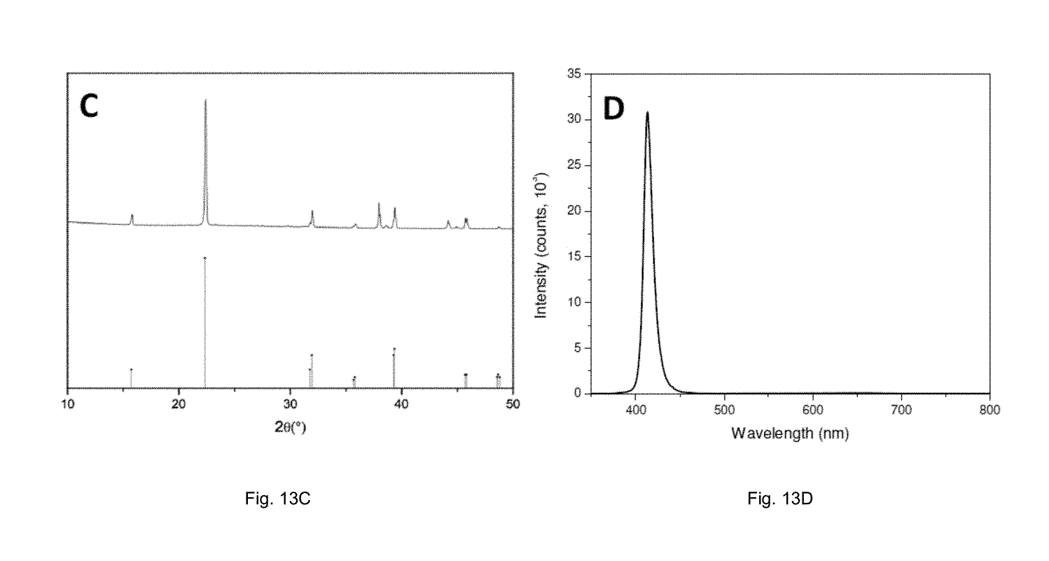

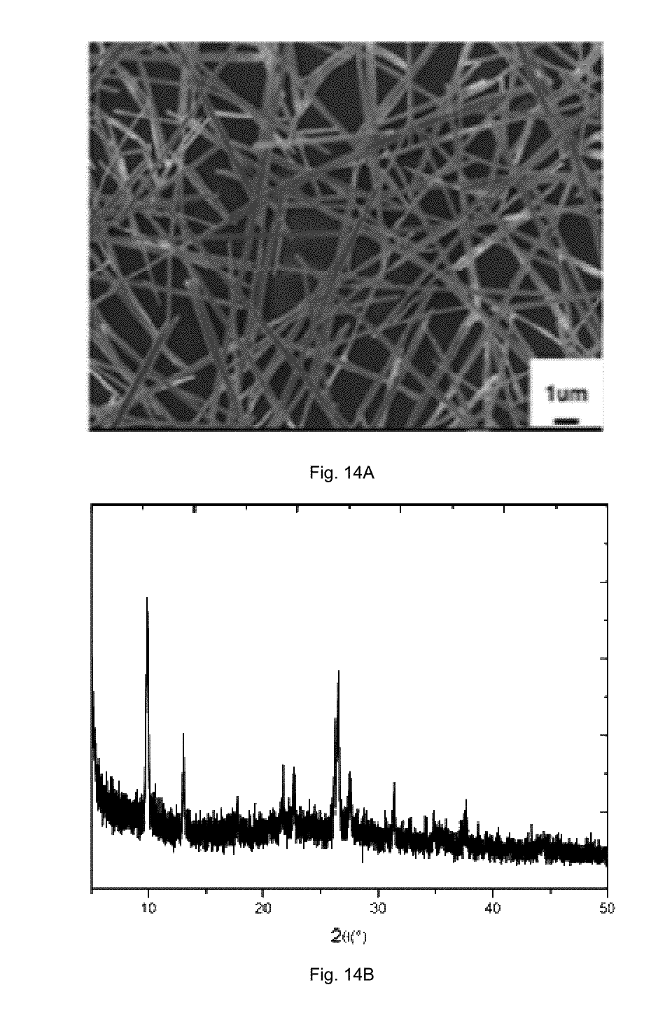

Single crystal nanowires of CsPbCl₃ were successfully synthesized by replacing CsBr with CsCl during the reaction, with the XRD pattern confirming the expected tetragonal phase of the as-grown CsPbCl₃. FIGS. 13A-13D show the results of the structural characterization of CsPbCl₃ nanowires. FIG. 13A shows an SEM image of an individual CsPbCl₃ nanowire. The scale bar is 5 microns. FIG. 13B shows a magnified SEM image depicting rectangular end facets. The scale bar is 1 micron. FIG. 13C shows the XRD pattern of the growth substrate indexed to the tetragonal phase of CsPbCl₃. Peaks with asterisks correspond to the aluminum sample stage. FIG. 13D shows the narrow PL emission centered at 418 nm observed from a single CsPbCl₃ nanowire. The smooth, rectangular facets of the CsPbCl₃ nanowires, as well as the strong PL emission centered at 411 nm, make them ideal for extending the wavelength range of CsPbX₃ nanowire lasers.

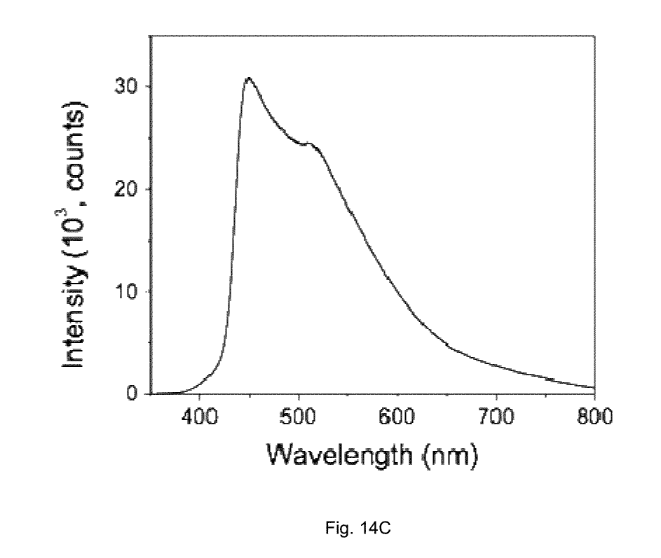

Attempts were also made to synthesize CsPbI₃ nanowires to achieve red emission and full coverage of the visible spectrum. FIGS. 14A-14C show the results of the structural characterization of CsPbI₃ nanowires. FIG. 14A shows SEM images showing the nanowires mesh structure. FIG. 14B shows that XRD pattern from the as-grown film assigned to the low temperature orthorhombic phase. FIG. 14C shows the band gap PL emission as well as broad, low energy emission due to self-trapped excitons.

A dense mesh of rough nanowires was obtained upon replacing CsBr with CsI (FIG. 14A). While the XRD pattern matched the orthorhombic phase of CsPbI₃ (Pbnm, FIG. 14B), the band gap emission of the nanowire mesh was centered at 448 nm along with a broad emission band peaked at 510 nm (FIG. 14C); this emission is characteristic of orthorhombic CsPbI₃ and has been previously ascribed to self-trapped exciton emission. The poor nanowire morphology may be attributed to the large tilt of the lead iodide octahedron in orthorhombic CsPbI₃ and the resulting lattice distortion away from the true cubic perovskite phase.

Three parameters affect the CsPbBr₃ nanowire growth process: CsBr-methanol concentration, reaction time, and reaction temperature. A specific CsBr-methanol concentration window is needed to synthesize the CsPbBr₃ perovskite composition. Pure CsPbBr₃ can be obtained under medium concentration (6 mg/mL to 10 mg/mL), without formation of the undesired CsPb₂Br₄ or Cs₄PbBr₆ stoichiometries. The dominate product was found to be CsPb₂Br₅ at low concentration (<4 mg/mL), and a mixture of Cs₄PbBr₆ and CsPbBr₃ at high concentration (>12 mg/mL). One reaction scheme consistent with these results is:

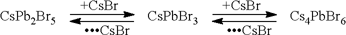

The right side the equation depicts the reaction of CsPbBr₃ with surplus CsBr to form Cs₄PbBr₆ at high concentrations of CsBr. The left side shows the release of CsBr from CsPbBr₃ at low concentrations to form CsPb₂Br₅. This hypothesis is consistent with the PbBr₂—CsBr phase diagram: all three compositions are thermodynamically stable at room temperature. Additionally, it has already been shown that certain chemical potentials (or concentrations) of CsBr correspond certain compositions.

During the initial stages of the reaction, the film color transitioned rapidly to red, then gradually to yellow. It is hypothesized that an intermediate CsPbIₓBr₃₋ₓ forms initially, then evolves to pure CsPbBr₃, as confirmed by XRD patterns at different growth times. The peaks corresponding to PbI₂ disappeared within the first 2 minutes, indicating that PbI₂ dissolves/reacts rapidly. For the intermediate products from 2 minutes to 10 minutes, the (001) peak was shifted ˜0.2° below that of pure CsPbBr₃; this is indicative of lattice expansion caused by the formation of CsPbIₓBr₃₋ₓ. Notably, researchers have reported intermediate CH₃NH₃PbI₂Br products during the growth of single crystal CsPbBr₃ nanostructures. Therefore, inorganic perovskite nanowires likely possess similar growth dynamics to hybrid perovskites.

Attempts to grow CsPbBr₃ using PbBr₂ and to grow CsPbCl₃ using PbCl₂ were made in order to simplify the synthetic process. However, neither provided as high of quality nanoscale products as PbI₂. When a film of PbBr₂ was used, the morphology of the as-grown CsPbBr₃ was found to be amorphous or polycrystalline rather than single crystalline as with PbI₂. For PbCl₂, limited solubility in DMF made spin coating a sufficiently thick film difficult.

It was determined that mild heating was useful for the formation of CsPbX₃ nanowires, as it speeds the dissolution-recrystallization process. One consequence of heating the reaction is the introduction of dislocations during nanowire growth. Mild heating likely enhances the solubility of the PbI₂ precursor in methanol, thus driving the resolution-recrystallization process and ultimately forming CsPbBr₃ nanostructures away from the film. For the nanowire geometry growth mechanism, screw dislocation-driven growth was proposed for the formation of CH₃NH₃PbX₃ nanowires as the spontaneous growth of single-crystal hollow tubes was observed. As similar single-crystal tube structures in the CsPbBr₃ growth process were observed, it is reasonable to hypothesize that inorganic perovskite nanowire growth is driven by an analogous mechanism.

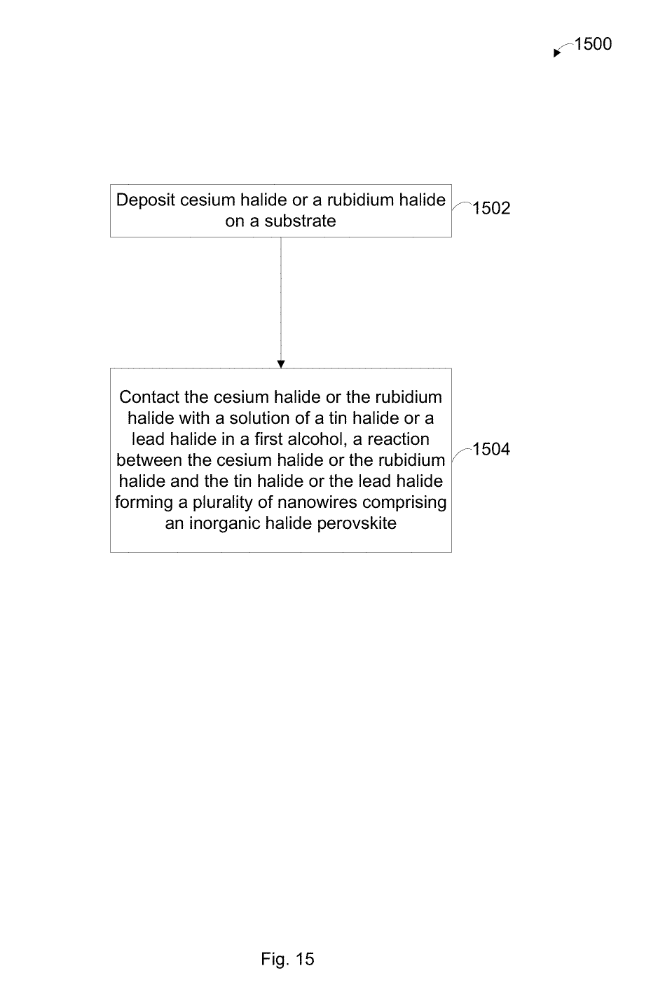

FIG. 15 shows an example of a flow diagram illustrating a fabrication process for inorganic halide perovskite nanowires. In some embodiments of the method 1500 shown in FIG. 15, a substrate is used in the fabrication process. In some embodiments of the method 1500, nanosheets are also generated. At block 1502 of the method 1500, a cesium halide or a rubidium halide is deposited on a substrate.

In some embodiments, depositing cesium halide or the rubidium halide on a substrate comprises depositing a solution of the cesium halide or the rubidium halide in a solvent on the substrate and then evaporating the solvent. Depositing the solution on the substrate may be performed with a spin coating process, for example. In some embodiments, the solvent comprises a solvent selected from a group consisting of methyl alcohol and dimethyl sulfoxide (DMSO). In some embodiments, evaporating the solvent comprises annealing the substrate at about 150° C. or less.

In some embodiments, the substrate comprises a material that the solution of the cesium halide or the rubidium halide in the solvent wets. In some embodiments, the substrate comprises a glass. In some embodiments, the substrate comprises silicon. In some embodiments, the glass is oxygen plasma treated. An oxygen plasma treatment may clean the glass and improve its wetting properties. In some embodiments, a polymer may be disposed on a surface of the substrate. The cesium halide or the rubidium halide solution may wet the polymer. For example, in some embodiments, the polymer comprises a hydrophilic polymer. In some embodiments, the polymer comprises a polymer selected from a group consisting of poly(3,4-ethylenedioxythiophene) (PEDOT), poly(3,4-ethylenedioxythiophene) polystyrene sulfonate (PEDOT:PSS), and polyaniline.

At block 1504, the cesium halide or the rubidium halide is contacted with a solution of a tin halide or a lead halide in a first alcohol. In some embodiments, the cesium halide or the rubidium halide is contacted with the solution of the tin halide or a lead halide in the first alcohol at less than about 100° C. for about 30 minutes to 150 minutes. For example, the substrate with the cesium halide or the rubidium halide disposed thereon may be immersed in a solution of the tin halide or the lead halide in the first alcohol. The halide of the tin halide or the lead halide is selected from a group consisting of chlorine, bromine, and iodine. A reaction between the cesium halide or the rubidium halide and the tin halide or the lead halide forms a plurality of nanowires comprising an inorganic halide perovskite. The first alcohol may comprise an anhydrous long chain alcohol. For example, in some embodiments, the first alcohol comprises propanol (e.g., 1-propanol or 2-propanol) or butanol (1-butanol, 2-butanol, 2-methyl-1-propanol, or 2-methyl-2-propanol). In some embodiments, the plurality of nanowires comprises ABX₃, wherein A is Cs or Rb, wherein B is Sn or Pb, and wherein X is Cl, Br, or I. In some embodiments, block 1504 is performed in an inert gas atmosphere.

In some embodiments, after block 1504, the plurality of nanowires is washed with a second alcohol. The second alcohol is used to clean the plurality of nanowires without damaging them. The second alcohol may comprise an anhydrous long chain alcohol. For example, in some embodiments, the second alcohol comprises propanol (e.g., 1-propanol or 2-propanol) or butanol (1-butanol, 2-butanol, 2-methyl-1-propanol, or 2-methyl-2-propanol). For example, in some embodiments, the second alcohol comprises isopropyl alcohol.

Using an embodiment of the method 1500 shown in FIG. 15 (e.g., a low temperature solution-phase process), CsSnI₃ nanowires were fabricated. The synthesis of black phase CsSnI₃ NWs has been a challenge because of the sensitivity of CsSnI₃ to moisture and oxidation. The black phase of CsSnI₃ has a direct band gap at 1.3 eV, which makes this material a good IR emitter and light absorber without the presence of toxic lead or cadmium or the use of highly reactive metal-organic chemical vapor deposition precursors. In addition, CsSnI₃ has intriguing electrical properties, with the electrical conductivity being several orders of magnitude larger than that of CsPbI₃ and CsPbBr₃.

The CsSnI₃ nanowires were synthesized on clean substrates that were loaded with a layer of CsI and allowed to react in a solution of SnI₂ in anhydrous 2-propanol. Specifically, to grow CsSnI₃ nanowires, Si or SiO₂ substrates were cleaned. After cleaning, the following operations were performed in an argon-filled glove box with an oxygen level of <0.1 ppm and a H₂O level of <2.0 ppm. A saturated solution of CsI in anhydrous methanol was prepared by allowing the solution to stir for at least 1 hour. Afterwards, the clean substrates were heated on a clean hotplate to 100° C. and allowed to equilibrate for 10 minutes. 70 μL of the saturated CsI solution was pipetted dropwise onto the hot substrates, which wetted the surface completely, without spilling. For substrates of different size, the volume of the CsI/MeOH was scaled to appropriately to wet the surface of the substrate without spilling. The substrates were allowed to completely dry for up to 30 minutes on the hotplate. Anhydrous dimethyl sulfoxide (DMSO) also can be used as a substitute for anhydrous methanol for this step. Afterwards, the CsI-coated substrates were placed in a clean 20 mL vial with the CsI-coated side facing up. The vial containing the CsI-coated chip was heated to 60° C. before the reaction began.

Separately, a saturated stock solution of SnI₂ in anhydrous 2-propanol was prepared (6.6 mmol/L) by stirring overnight, and the solution was diluted to 4 mmol/L to 0.3 mmol/L by diluting with anhydrous 2-propanol. To begin the reaction, 1 mL of SnI₂/2-propanol solution was pipetted onto the warm CsI-coated substrates, and the vial was capped and allowed to react for 90 minutes to 120 minutes. The substrates darkened with the nucleation and growth of CsSnI₃ in the SnI₂/2-propanol solution.

To stop the reaction, the substrate was lifted out of the solution and tipped towards the corner. Any excess solution was wiped away with a cloth to absorb the growth solution while minimizing the deposition of salts on the chip after evaporation of the growth solution. Optionally, the sample can be quickly washed in anhydrous 2-propanol and dried in the same manner. After synthesis, the sample was stored and transported in a sealed centrifuge tube to minimize air/humidity exposure.

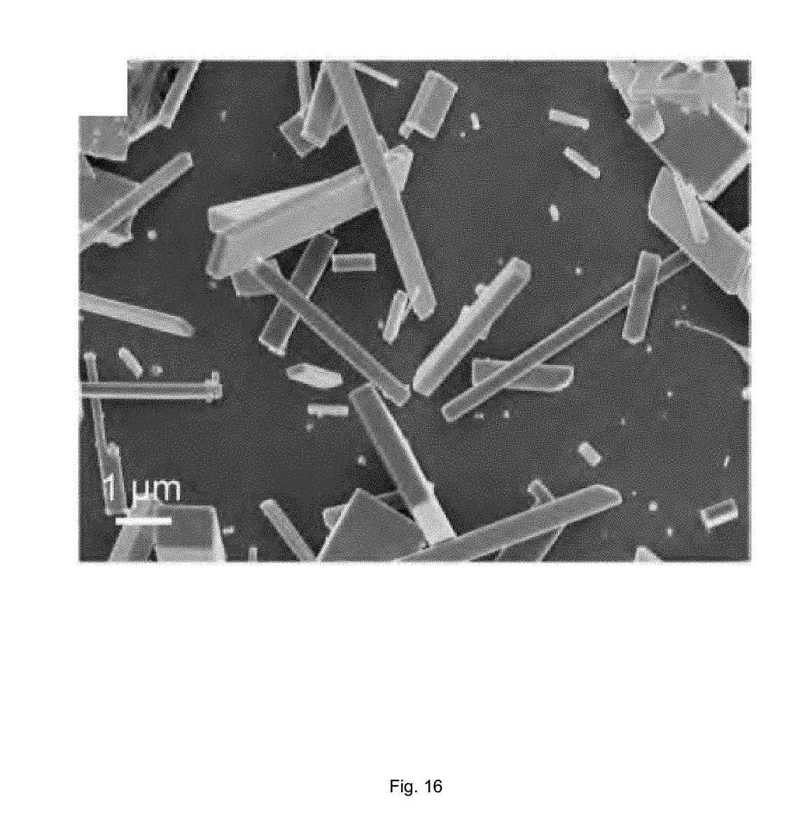

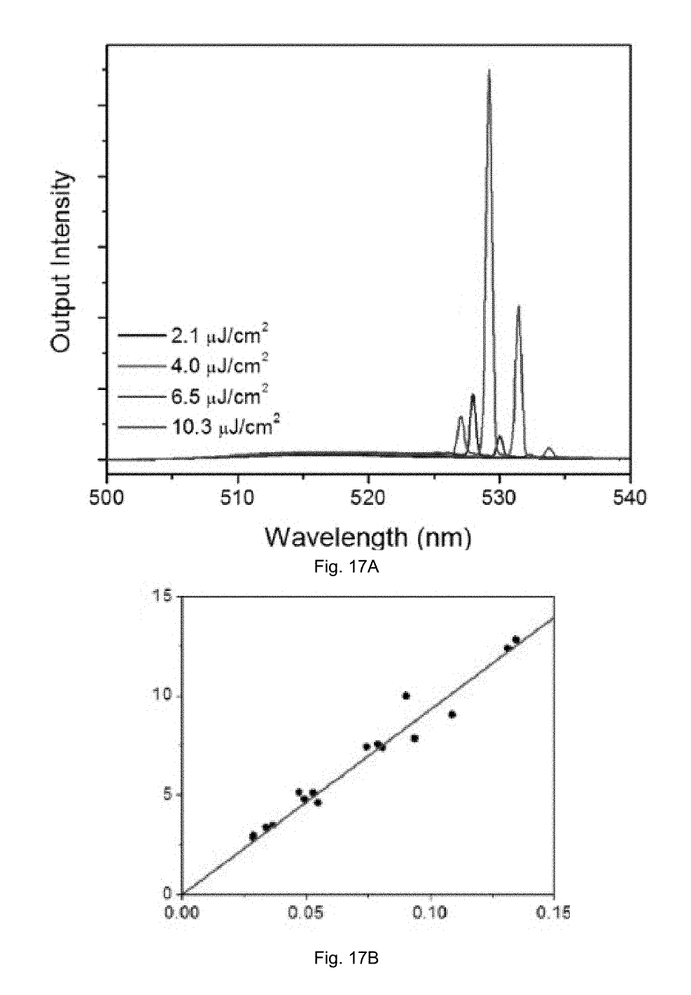

The CsSnI₃ nanowires were characterized. FIG. 16 shows an example of a micrograph of as-synthesized CsSnI₃ nanowires. The CsSnI₃ nanowires had high electrical conductivity and ultralow thermal conductivity. This makes the CsSnI₃ nanowires good candidates for use in thermoelectric devices and thermal barrier coatings. For example, CsSnI₃ nanowires could be used to fabricate an electrically conductive thermal barrier coating.

Using the methods described above, inorganic halide perovskite nanowires can be fabricated that are large enough (i.e., a large enough diameter or a large enough cross-sectional dimension) to support photonic lasing. In order to achieve lasing with some halide perovskite compositions, nanowires with diameters greater than about 180 nm are needed. For example, some embodiments of the method 1100 shown in FIG. 11 can generate nanowires that are large enough to support photonic lasing.

Photonic lasing arises from the unique ability of a nanowire to act as both gain medium and laser cavity. Forming the nanowire from a stable, highly absorptive and emissive material allows for stimulated emission to occur upon reaching a sufficient carrier density. The nanowire geometry defines the laser cavity which is bounded on either end by the nanowire end facets. The difference in refractive index between the nanowire and its environment (atmosphere, substrate, etc.) generates significant end facet reflectivity as well as providing efficient wave guiding along the length of the wire. For CsPbBr₃ nanowires, lasing was achieved via optical excitation from a femtosecond pulsed laser. At excitation densities below the lasing threshold, spontaneous emission dominates, and the nanowire was uniformly emissive. Upon surpassing the threshold, however, stimulated emission takes over and a periodic pattern was observed, which is caused by interference of the coherent emission from the two end facets of the nanowire.

The dependence of the PL spectral response on increasing excitation fluence is shown in FIG. 17A. The spontaneous emission from a CsPbBr₃ nanowire is centered at 516 nm with a 16 nm (74 meV) full-width half maximum. The spontaneous emission peak first increases with increasing excitation intensity, then plateaus as narrow (0.51 nm minimum), closely spaced peaks emerge on the red edge of the emission spectrum near 532 nm and grow rapidly with excitation intensity. The narrow peaks correspond to Fabry-Pérot lasing modes as the mode spacing is found to change linearly with the inverse of the nanowire length (FIG. 17B). The power-dependent output intensity follows the typical “S”-curve shape and depicts all three PL regimes: spontaneous emission dominates at low excitation intensities until the onset of lasing near 5 μJ cm⁻² (Pₜₕ), the superlinear PL increase indicative of amplified spontaneous emission follows, and finally gain-pinning and the emergence of lasing occurs past 10 μJ cm⁻².

Analysis of the individual peak widths from the spectra in FIG. 17A provides information about the nanowire laser cavity quality (Q) factor, or how well the cavity confines and amplifies emission. The Q-factor is mode dependent with stronger modes possessing higher values since this corresponds to more efficient amplification and thus higher emission intensity. Using the relationship Q=λ/δλ, where λ is the peak center wavelength and δλ is the peak width, a maximum, single mode Q-factor of 1009±5 was determined with an average of 960±60 when considering the four major modes.

Time-resolved PL was used to measure the carrier population dynamics of the laser cavity above and below the lasing threshold. Below the lasing threshold, the nanowire PL signal decays biexponentially with the rapid component (154±2 ps, 81%) contributing much more than the slower component (970±20 ps, 19%). The rapid component is attributed to surface state recombination and the longer component to bulk recombination. When the excitation fluence is increased past the lasing threshold, an additional decay component is observed (10.4±0.3 ps, 87%), which decays more rapidly than the other components (110±2 ps, 11%; 720±20 ps, 2%) as well as the instrument response (˜30 ps). This rapid decay corresponds to the stimulated emission process depleting carriers that would otherwise undergo spontaneous emission. The lasing threshold and Q-factor place these nanowires in the upper tier of nanowire lasers and clearly demonstrate the effectiveness of CsPbBr₃ as a gain medium.

The mechanism for optical gain by stimulated emission in perovskite nanostructures is still under investigation. In CsPbX₃ quantum dots (QDs), support for both single exciton and biexciton lasing has been demonstrated. In the case of biexciton-driven stimulated emission, a 50 meV red-shifted emission band was assigned to biexciton recombination, in agreement with expected biexciton binding energies in CsPbX₃ QDs. While a similar asymmetric red-shifted emission band was observed, the red-shift of 69 meV is larger than expected for biexciton binding energies in non-colloidal CsPbBr₃ nanowires. Instead, it is postulated that an electron-hole plasma (EHP) mechanism is responsible for stimulated emission, as proposed in well-known compositions such as ZnO and GaN as well as in recent CH₃NH₃PbX₃ nanowires. An EHP is formed in bulk crystals when the carrier density surpasses the Mott density. Here, the carrier density at the lasing threshold was estimated to be ˜1×10¹⁸ cm⁻³ by FDTE simulation, an order of magnitude greater than the bulk CsPbBr₃ Mott density of ˜2×10¹⁷ cm⁻³. In addition, the formation of an EHP is expected to lead to a blue-shift in the cavity modes due to a decrease in the refractive index that arises from exciton absorption saturation. A blue-shift of 2 nm with increasing excitation fluence was observed, and it is therefore reasonable that an EHP mechanism is responsible for stimulated emission in CsPbX₃ nanowires. Further study is needed, however, to elucidate the stimulated emission carrier dynamics.

Cesium lead halide materials have been shown to be stable when exposed to moisture or heat, making them attractive for real-world application. The CsPbBr₃ nanowires are stable for days under ambient atmosphere and illumination without loss of morphology. Additionally, the material composition remains intact over the course of months and does not separate into PbI₂ and other byproducts as has been demonstrated for some hybrid materials. CsPbBr₃ nanowires are also stable under constant, pulsed excitation above the lasing threshold. Nanowires were excited to 1.2 Pₜₕ under either a closed nitrogen atmosphere or ambient atmosphere (50±1% relative humidity) and the integrated emission intensity was monitored. The results indicate significant operating lifetimes even under atmospheric conditions. In both cases, initial burn-in was observed where the integrated emission amplitude exceeds 100%. Under nitrogen, nanowire lasing continues uninterrupted for longer than one hour or over a billion excitation cycles, and the nanowire was undamaged after this time. Under atmospheric conditions, the burn-in time was accelerated, but the decrease in lasing intensity did not occur until longer than 25 minutes of continuous exposure to high-energy pulsed excitation. In contrast, the long-term lasing stability of methyl ammonium lead halide nanowire lasers has never been demonstrated. The stable, continuous lasing operation observed here is promising for future applications as it suggests both high photo- and thermal stability under both ideal and sub-optimal environmental conditions.

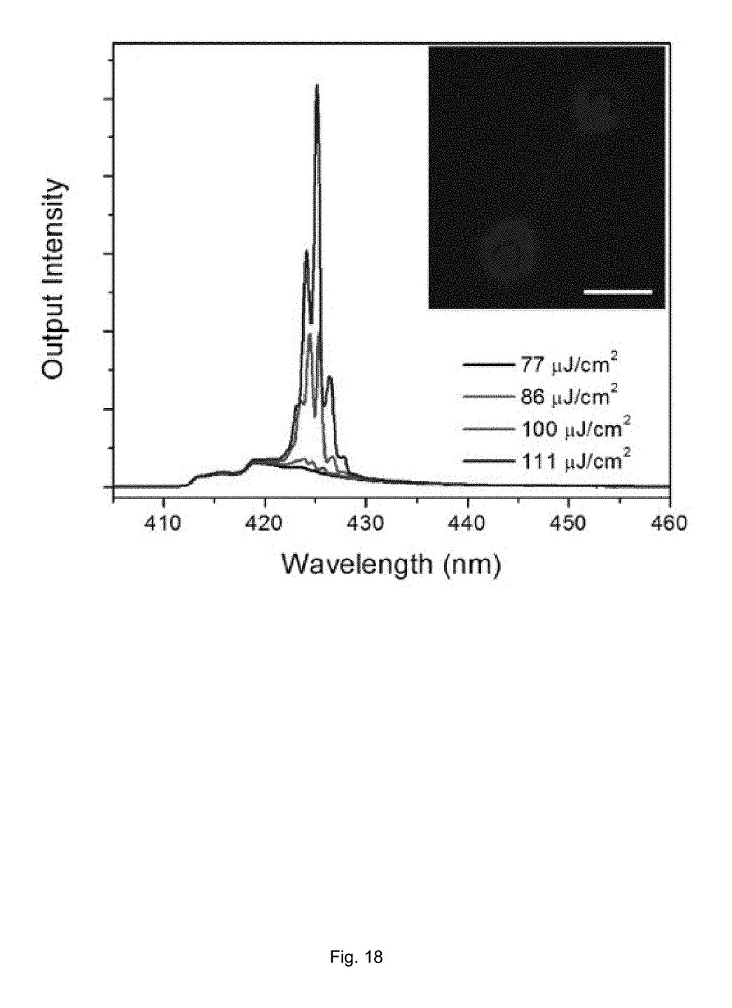

Lasing was also demonstrated for CsPbCl₃ nanowires. Upon focused excitation, lasing occurred near 430 nm with the emergence of narrow peaks similar to CsPbBr₃ nanowires, as shown in FIG. 18. The lasing threshold was found at approximately 86 μJ cm⁻², significantly higher than for CsPbBr₃ nanowires, and the Q-factor was consequently found to be lower, with a maximum of 690±70 and an average of 580±120. Nevertheless, interference from end facet emission was observed (FIG. 18, inset) indicating effective waveguiding and coherent emission from the nanowire. While the orthorhombic phase of CsPbI₃ is unsuitable for lasing, halide alloying may be pursed in the future to achieve broad wavelength tunability as observed in CH₃NH₃PbX₃ materials.

Embodiments of the methods described herein (e.g., the method 100 shown in FIG. 1) can be modified so that nanoplates (which are also referred to as nanosheets) are generated. Nanoplates are two-dimensional nanostructures. In some embodiments, nanoplates have a thickness of about 0.34 nm (e.g., graphene) to 100 nm or about 1 nm to 100 nm. In some embodiments, cesium lead halide perovskite nanoplates are fabricated. In some embodiments, an anion exchange reaction is performed on the nanoplates. For example, instead of performing an anion exchange reaction on nanowires as described in the methods 500 and 510 shown in FIGS. 5A and 5B, an anion exchange reaction is performed on nanoplates.

In an example embodiment, the colloidal synthesis of CsPbBr₃ perovskite nanoplates was performed using air-free techniques. First, a cessium oleate solution was prepared. Briefly, 0.4 g Cs₂CO₃ and 1.2 mL OA were loaded into a 3-neck flask along with 15 mL ODE, degassed under vacuum at 120° C. for 1 h, following a second degassing phase at 150° C. under Ar until all Cs₂CO₃ reacted with OA.

ODE (5 mL) and PbBr₂ (0.069 g) were loaded into 25 mL 3-neck flask and dried under vacuum for 1 hour at 120° C. Dried oleylamine (0.5 mL) and dried OA (0.5 mL) were injected at 120° C. under Ar. After complete solubilisation of a PbBr₂ salt, the temperature was changed to 90° C. to 130° C. and hot (˜100° C.) Cs-oleate solution (0.4 mL, 0.125 M in ODE, prepared as described above) was quickly injected. The reaction mixture then was immediately cooled by the ice-water bath. The temperatures of 90° C. to 130° C. tend to strongly favor asymmetric growth producing quasi 2D geometries.

The nanoplates were extracted from the crude solution by centrifuging at 8500 RPM for 5 minutes. Lower temperature reactions (where the crude solution concentration is smaller) and where thinner nanoplates are formed demand longer centrifugation times and cooling the solution to 17° C. (above freezing point of ODE). After centrifugation, the supernatant was discarded and the particles were redispersed in hexane forming stable colloidal solutions. Further cleaning of the perovskite nanoplates can be performed.

The ionic nature of the metathesis reaction dictates the rapid nucleation and growth kinetics of the resulting nanocrystals. The reaction temperature plays a critical role in determining the shape and thickness of the resulting nanoplates. Reactions conducted at 150° C. produce mostly symmetrical nanocubes with green-color photoluminescent (PL) emission. Reactions conducted at lower temperatures present blue-shifted PL spectra. For example, at 130° C. lower symmetry nanoplates with cyan emission are formed. At 90° C. and 100° C., very thin nanoplates were detected along with lamellar structures ranging 200 nm to 300 nm in length. As TEM images showed, nanoplates grow along and inside these lamellar structures, suggesting that organic mesostructures serve as growth directing soft templates that break the crystal's inherent cubic symmetry and dictate the 2D growth. Such a mechanism is not without precedent, where a similar soft templating mechanism was reported for wurtzite CdSe nanoplates. Reaction temperatures as low as 70° C. resulted in almost transparent suspensions, where TEM showed amorphous micron size sheets with almost no crystals present. These objects may be unreacted precursors. Interestingly, reactions at temperatures of 170° C. to 200° C. produced larger nanocubes and at longer reactions times high aspect ratio nanowires. Recent reports suggest these geometries evolve sequentially from each other.

### CONCLUSION

Further details regarding the embodiments described herein can be found in the following references, all of which are herein incorporated by reference:
Zhang et al., “Solution-Phase Synthesis of Cesium Lead Halide Perovskite Nanowires,” J. Am. Chem. Soc., 2015, 137 (29), pp. 9230-9233;
Eaton et al., “Lasing in Robust Cesium Lead Halide Perovskite Nanowires,” Proceedings of the National Academy of Sciences, 2016, vol. 113 no. 8, pp. 1993-1998;
Zhang et al., “Synthesis of Composition Tunable and Highly Luminescent Cesium Lead Halide Nanowires through Anion-Exchange Reactions,” J. Am. Chem. Soc., 2016, 138 (23), pp 7236-7239;
Zhang et al., “Ultrathin Colloidal Cesium Lead Halide Perovskite Nanowires,” J. Am. Chem. Soc., 2016, 138 (40), pp 13155-13158; and
Bekenstein et al., “Highly Luminescent Colloidal Nanoplates of Perovskite Cesium Lead Halide and Their Oriented Assemblies,” J. Am. Chem. Soc., 2015, 137 (40), pp 16008-1601.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

What is claimed is:

1. A nanowire comprising:
an inorganic halide perovskite comprising ABX₃, A being Cs or Rb, B being Sn or Pb, and X being selected from a group consisting of Cl, Br, I, a combination of Br and Cl, and a combination of Br and I.

2. The nanowire of claim 1, wherein the nanowire has a cross-sectional dimension of less than 1000 nanometers.

3. The nanowire of claim 1, wherein the nanowire comprises a single crystal.

4. The nanowire of claim 1, wherein the nanowire has an orthorhombic crystal structure.

5. The nanowire of claim 1, wherein the nanowire has a length of about 100 nanometers to 30 microns.

6. A method comprising:
(a) providing a first solution comprising cesium oleate or rubidium oleate in a first organic solvent;
(b) providing a second solution comprising a lead halide and a surfactant in a second organic solvent, the halide being selected from a group consisting of chlorine, bromine, and iodine; and
(c) mixing the first solution and the second solution, a reaction between the cesium oleate or the rubidium oleate and the lead halide forming a plurality of nanowires comprising an inorganic lead halide perovskite.

7. The method of claim 6, wherein the first organic solvent comprises octadecene (ODE), and wherein the second organic solvent comprises a solvent selected from a group consisting of ODE and oleylamine.

8. The method of claim 6, wherein the surfactant comprises a surfactant selected from a group consisting of octylamine, oleylamine, oleic acid, and combinations thereof.

9. The method of claim 6, wherein operation (c) is performed at about 130° C. to 250° C. for about 5 minutes to 20 hours.

10. The method of claim 6, wherein operations (a), (b), and (c) are performed in an inert gas environment.

11. The method of claim 6, wherein nanowires of the plurality of nanowires comprise ABX₃, wherein A is selected from a group consisting of cesium (Cs) and rubidium (Rb), wherein B is lead (Pb), and wherein X is selected from a group consisting of chlorine (Cl), bromine (Br), and iodine (I).

12. The method of claim 6, wherein nanowires of the plurality of nanowires are single crystals having an orthorhombic crystal structure.

13. The method of claim 6, wherein nanowires of the plurality of nanowires comprise CsPbX₃, wherein X comprises a first halide selected from a group consisting of chlorine (Cl), bromine (Br), and iodine (I), the method further comprising:
contacting the plurality of nanowires with a third solution including a long-chain ammonium halide including a second halide, the second halide being a different halide than the first halide and being selected from a group consisting of Cl, Br, and I, and at least some of the first halide of the nanowire being replaced with the second halide.

14. The method of claim 13, wherein the contacting is performed for about 1 minute to 7200 minutes.

15. The method of claim 13, wherein the solvent of the third solution including the long-chain ammonium halide comprises a non-polar solvent.

16. The method of claim 13, wherein the nanowires of the plurality of nanowires have an orthorhombic crystal structure before the contacting the plurality of nanowires with the third solution, and wherein nanowires of the plurality of nanowires have an orthorhombic crystal structure after the contracting the plurality of nanowires with the third solution.

17. The method of claim 13, wherein contacting the nanowire with the third solution is performed in an inert gas environment.

18. The method of claim 13, wherein the temperature of the third solution is about 40° C. to 80° C.

19. The method of claim 6, wherein operation (c) generates a plurality of nanostructures comprising an inorganic lead halide perovskite, the plurality of nanostructures comprising a first plurality of nanostructures, the plurality of nanowires, a first plurality of nanowires, and a first plurality of nanoparticles, nanostructures of the first plurality of nanostructures and nanowires of the plurality of nanowires having a larger size than nanowires of the first plurality of nanowires and nanoparticles of the plurality of nanoparticles, the method further comprising:
separating the first plurality of nanostructures from the first plurality of nanowires and the first plurality of nanoparticles;
adding a first specified amount of an anti-solvent to a liquid in which the first plurality of nanowires and the first plurality of nanoparticles are suspended; and
separating the first plurality of nanowires from first nanoparticles of the first plurality of nanoparticles, the first nanoparticles having a first size and sizes larger than the first size.

20. The method of claim 19, further comprising:
adding a second specified amount of the anti-solvent to a supernatant including the first plurality of nanowires and the first plurality of nanoparticles, the second specified amount being larger than the first specified amount; and
separating the first plurality of nanowires from second nanoparticles of the first plurality of nanoparticles, the second nanoparticles having a second size, the second size being smaller than the first size.
